(19) United States
(12) Patent Application Publication
(10) Pub. No.: US 2025/0208566 A1
(43) Pub. Date: Jun. 26, 2025

(54) SYSTEM AND METHOD FOR GENERATING HOLOGRAPHIC OPTICAL IMAGES IN CURABLE MATERIAL

(71) Applicant: Nanografix Corporation, San Diego, CA (US)

(72) Inventors: Daniel Lieberman, San Diego, CA (US); Ori Lieberman, San Diego, CA (US)

(21) Appl. No.: 18/847,192

(22) PCT Filed: Mar. 15, 2023
(86) PCT No.: PCT/US2023/015302

§ 371 Date: Sep. 13, 2024

Related U.S. Application Data
(60) Provisional application No. 63/320,200, filed on Mar. 15, 2022.

(51) Int. Cl. G03H 1/02; G03H 1/00

(52) U.S. Cl. CPC G03H 1/0244; G03H 1/0011; G03H 1/0256; G03H 1/028; G03H 2250/34

(57) ABSTRACT

A system for generating variable optical images in curable material using generic optical matrices, the system including an applicator configured to apply the curable material to a portion of a substrate supported by a carrier web; a transparent roller comprising surface elements formed on an outside surface of the transparent roller, the transparent roller being configured to form optical structures in the curable material, wherein the surface elements on the transparent roller form the optical structures in the curable material when the surface elements contact the curable material as the substrate travels over the outside surface of the transparent roller; a radiation source within or outside the transparent roller configured to cure the curable material after the optical structures are formed in the curable material; and an image generation component configured to obliterate portions of the optical structures to form a predetermined image.

### CROSS-REFERENCE TO RELATED APPLICATION

This application claims priority to U.S. Provisional Patent Application, Ser. No. 63/320,200 titled “System And Method For Generating Holographic Optical Images In Curable Material”, filed Mar. 15, 2022, the disclosure of which is incorporated by reference herein in its entirety.

### FIELD OF THE INVENTION

This disclosure generally relates to a system and method for producing holographic optical images with encrypted information in a curable material. More particularly, in a printing process using a web supporting a substrate, curable material is only applied to a portion of the substrate and the roller has surface elements on its outside surface that form optical structures in the curable material.

### BACKGROUND

Optical images that create two-dimensional and/or three-dimensional effects may typically be produced by printing, embossing or engraving on substrates using lenticular and integral lens techniques, microlens sets array techniques, holographic techniques, electro beam techniques, specular techniques, dot matrix techniques, light field techniques, electron beam techniques, stereographic techniques, and/or three-dimensional printing. These techniques create surface reliefs that are replicated in a substrate or one or more layers or coatings on the substrate.

A need has arisen in the printing industry for the capability of generating two-dimensional and/or three-dimensional effects on a substrate or one or more layers or coatings on the substrate at low cost and of integrating them into conventional printing machinery so that they can easily be incorporated in printed materials such as labels, laminates, packaging, security documents, identification documents, lottery tickets and/or other printed materials.

The implementation of optical images that create two-dimensional and/or three-dimensional effects within printing applications has generally been costly and time-consuming. In the case of holograms, these may be produced by holographic companies that have very expensive equipment. The process may be slow and costly. Contemporary hologram technology may require companies that have an optical laboratory in which the hologram is made on a photoresist plate. The optical laboratory may include laser equipment, anti-vibration tables, other specialized equipment, and trained personnel. Once a hologram is initially made, it may be called a master, but it may not be used for large-scale production. As such, the company may also need an electroforming laboratory, where the photoresist master is introduced into a bath of nickel sulfamate for the purpose of cultivating a nickel copy on the surface of the photoresist. Once the nickel is of sufficient thickness, it may be separated from the photoresist copy in order to create a negative copy of the original image. It is from this nickel that the laboratory may cultivate a series of copies that may later be called nickel shims and may be used to engrave the image on a variety of supporting materials.

In order to engrave the image, it may be necessary to have special equipment. Depending on the final product, there may be additional equipment for different applications. These processes often take several days and are processes that are completely distinct from ink printing. For the purpose of using these optical structures, the printers customarily rely on specialized companies (e.g., holographic companies) that generate the required images according to their needs. In addition to the investment of additional time needed to interface with those specialized companies, printers may be required to invest in equipment that enables the printer to transfer the optical structures onto their printed products.

Similar to the photoresist plate and shim method discussed above, embossing or imprinting techniques using a master cylinder or roller and different shims for different desired holograms have similar drawbacks. Etching desired structures into each shim is time consuming and expensive and may require specialized equipment such as laser equipment. Individual shims also wear out over time and continued use.

### SUMMARY

In accordance with one aspect of the present disclosure, a system for generating variable optical images in curable material using generic optical matrices includes an applicator configured to apply the curable material to a portion of a substrate supported by a carrier web. The system also includes a transparent roller having surface elements formed on an outside surface of the transparent roller. The transparent roller is configured to form optical structures in the curable material. The surface elements on the transparent roller form the optical structures in the curable material when the surface elements contact the curable material as the substrate travels over the outside surface of the transparent roller. The system also includes a radiation source within the transparent roller configured to cure the curable material after the optical structures are formed in the curable material. The system also includes an image generation component configured to obliterate portions of the optical structures to form a predetermined image.

In accordance with another aspect of the present disclosure, a method for producing holographic optical images in a curable material includes applying, by an applicator, a curable material to a portion of a substrate. The method also includes forming optical structures in the curable material by a transparent roller. The transparent roller includes surface elements formed on an outside surface of the transparent roller. The surface elements on the transparent roller form the optical structures in the curable material when the surface elements contact the curable material. The method also includes curing, by a radiation source within the transparent roller, the curable material after the optical structures are formed on the curable material. The method also includes obliterating, by an image generation component, portions of the optical structures to form a predetermined image.

Other advantages of the present disclosure will become readily apparent from the following detailed description. The present disclosure is capable of other and different embodiments, and its several details are capable of modifications in various obvious respects, all without departing from the present disclosure. Accordingly, the drawing and description are illustrative in nature, not restrictive.

### BRIEF DESCRIPTION OF THE DRAWINGS

The foregoing aspects and many of the attendant advantages of the disclosed embodiments will become more readily appreciated by reference to the following detailed description, when taken in conjunction with the accompanying drawings, wherein:

FIG. 1 depicts a system for generating variable optical images in curable material using generic optical matrices, in accordance with one or more implementations.

FIG. 2 illustrates a curable material applied to a portion of a substrate by an applicator, in accordance with one or more implementations.

FIG. 3A illustrates a cured surface relief pattern on the substrate after optical structures are formed in the curable material by a transparent roller, in accordance with one or more implementations.

FIG. 3B illustrates another embodiment of forming optical structures in a curable material with a transparent roller, in accordance with one or more implementations.

FIGS. 4A and 4B illustrate schematic diagrams of substrates that can be used with the system of FIGS. 1-3, in accordance with one or more implementations.

FIG. 5 illustrates a schematic diagram of a roller's surface element having a matrix of pixels corresponding to color and sub-pixels corresponding to non-color effects, in accordance with one or more implementations.

FIG. 6 also illustrates a schematic diagram of a roller outer surface matrix having pixels corresponding to color and sub-pixels corresponding to non-color effects, in accordance with one or more implementations.

FIG. 7 illustrates a schematic diagram of an exemplary array of elements on a roller, in accordance with one or more implementations.

FIG. 8 illustrates an exemplary image formed in the cured material on the substrate by an inkjet printer, in accordance with one or more implementations.

FIG. 9 illustrates a schematic diagram of an exemplary image formed in the cured material on the substrate by one or more image generation components, in accordance with one or more implementations.

FIGS. 10A and 10B illustrate schematic diagrams of a mask used to generate an exemplary image formed in the cured material on the substrate by one or more image generation components, in accordance with one or more implementations.

FIGS. 11A and 11B illustrate a schematic diagrams of a digital light processor projector used to generate an exemplary image formed in the cured material on the substrate by one or more image generation components, in accordance with one or more implementations.

FIG. 12 illustrates a schematic diagram of a stereolithography device used to generate an exemplary image formed in the cured material on the substrate by one or more image generation components, in accordance with one or more implementations.

FIG. 13 illustrates a flow diagram of a method for producing holographic optical images in a curable material, in accordance with one or more implementations.

### DETAILED DESCRIPTION

In the following description, for the purposes of explanation, numerous specific details are set forth in order to provide a thorough understanding of the present disclosure. It will be apparent, however, to one skilled in the art that the present disclosure may be practiced without these specific details.

A system for generating variable optical images in curable material using generic optical matrices is described. A method for producing holographic optical images in a curable material is also described. One aspect of the disclosure includes a novel transparent roller having a predetermined matrix of surface elements with surface reliefs, that form optical structures that can be used to generate images with holographic effects (described in detail below) that cannot be generated by existing roller surfaces. In this aspect, the matrix of surface elements may have surface elements with surface reliefs corresponding to color (pixels) and surface reliefs corresponding to non-color effects (sub-pixels). For example, the pixels may include first pixels corresponding to a first color and second pixels corresponding to a second color. The sub-pixels may include first sub-pixels corresponding to a first non-color effect and second sub-pixels corresponding to a second non-color effect.

The disclosed transparent roller can be used to create optical structures in a substrate carrying curable material that is embossable (i.e., material that can be embossed or imprinted). Embossable material may have one or more layers of an embossable material and/or an embossable coating. For example, an embossable material may include an embossable lacquer and may also include one or more of a vacuum deposited aluminum layer and/or HRI layer. In some implementations, substrates may be film or paper with one or more layers or coatings of embossable material in certain locations and may be metallized or have a high refractive index. An embossable material may also be made of a soft material, such as PVC, BOPP or OPP. Other embossable materials can be used as well. The optical structures created in the curable embossable material generate images with holographic effects, such as 2-dimensional and 3-dimensional effects, multi-color effects and stereo- and depth effects including sequential numbers, sequential QR codes, text and optical encrypted information. In some implementations, the substrate carrying the curable embossable material may also be embossable and may be pre-embossed with optical structures to create additional and novel optical effects in the substrate.

The disclosed system and method generally includes a roller that includes surface elements, or optical structures, formed on the outside of the roller. The surface elements on the roller form optical structures in the curable material when the surface elements contact the curable material. The surface elements on the roller form a surface relief pattern, and the optical structures in the curable material form a generic optical matrix. As will be described below in more detail, the optical structures may be gratings, holograms, photonic structures or any other optical structure that is made from the surface relief pattern of the surface elements when the surface elements contact the curable material. The optical image may be a holographic effect, a stereo effect, an optical effect, or an optically variable security encrypted information. The optical images may vary with every print cycle, such that different optical images are instantly produced in a single printing cycle. Once the optical images are generated using the generic optical matrices, the optical images may be coated with nanoinks in order to make them either metallized or highly reflective with diffractive index nanoinks.

Generally, the system may include three stations or modules. First, a substrate that has a printed label on it may be fed into the system. In the first station of the system, an embossable curable material (e.g., a lacquer) may be printed onto a desired area of the substrate, such as on a portion of the label using an inkjet printer in any desired shape or size. In the second station, there is a transparent roller that has microscopic optical structures formed on the outside of the roller. The substrate may be fed into the second station and the roller may be used to emboss or imprint microscopic optical structures onto the curable material. The structures may be a type of “generic optical matrix” of microscopic or nanoscopic optical structures, such as holographic structures (i.e., pixels). The roller may also include a radiation source (e.g., ultraviolet, or “UV,” light source) inside or outside the roller which cures the curable material after the optical structures are formed in the curable material. In the third station, a holographic image with encrypted information may be formed in the cured material. The image may be formed by obliterating certain optical structures according to digital information about a desired image sent to the third station. The digital information may be used to identify which optical structures to obliterate in the cured material in order to create the desired holographic image. The image may contain encrypted information. The optical structures may be obliterated using a laser to destroy the desired optical structures or using a conventional printer to print ink over desired optical structures. The optical structures may also be covered with another curable material and cured at different wavelengths in order to obliterate the desired optical structures.

Exemplary implementations may provide to printers an ability to control all aspects of their production, including the generation of complex optical images (e.g., holograms) without having to invest in expensive and complex optics and equipment for the application thereof. In other words, exemplary implementations may facilitate continuous systems that are easily and inexpensively integrated into printers' prepress and production departments. As a result, printers may be able to supply their clients quickly with a combination of prints and complex optical images at reasonable cost during prepress and production.

Some implementations may facilitate instantly or rapidly creating optical structures on a large-scale to create many types of images without the use of laser, electroforming, expensive molds, and/or embossing equipment. Applications of these optical structures may include emphasizing the aesthetic effect of a label; providing 3D prints for augmented reality and/or virtual reality systems (e.g., Microsoft® HoloLens™); making packaging more attractive to the consumer; adding security to government documents, paper currency, credit cards, passports, labels, packaging, and/or other security applications; track and trace applications; scratch-off lottery tickets; RFID antennas combined with variable optical images using three-dimensional printers; and/or other applications.

Some implementations may enable the disclosed system to vary the optical image that is being printed. According to some implementations, they may facilitate creating optical structures in such a manner that they are variable, meaning that after individual printing cycles a new and different optical image can be instantly produced. For example, an optical image may change from label to label with a purpose of increasing security of the product on which the label has been adhered, and/or with a purpose of personalizing packaging with a unique optical characteristic for individual packages. This is digital printing of optical structures.

Some implementations may be used with traditional printing equipment, digital equipment, desktop printers, and/or other equipment setups with the purpose of producing optical structures continuously or on demand with the ink printing of these machines. As such, the cost of generating these optical images may be dramatically reduced and may approach costs that are more similar to those of pre-printing in the printing industry.

In some implementations, the disclosed transparent roller may have surface elements with surface reliefs that relate to views from a person's left and right eye and also relate to color, such as red, green and/or blue, and can be used to create full color, 2D/3D, 3D optical images or images that have encrypted information. The surface reliefs may be optical structures, such as gratings, holograms, photonic structures or any other optical structure that is made from surface reliefs.

In some implementations, the disclosed transparent roller may be made of plastic, quartz, glass, etc. and have engraved surface elements with surface reliefs that are made by ion etching, chemical etching, laser engraving, transparent shims, or any other method that can be used to create surface reliefs in the surface of the transparent roller.

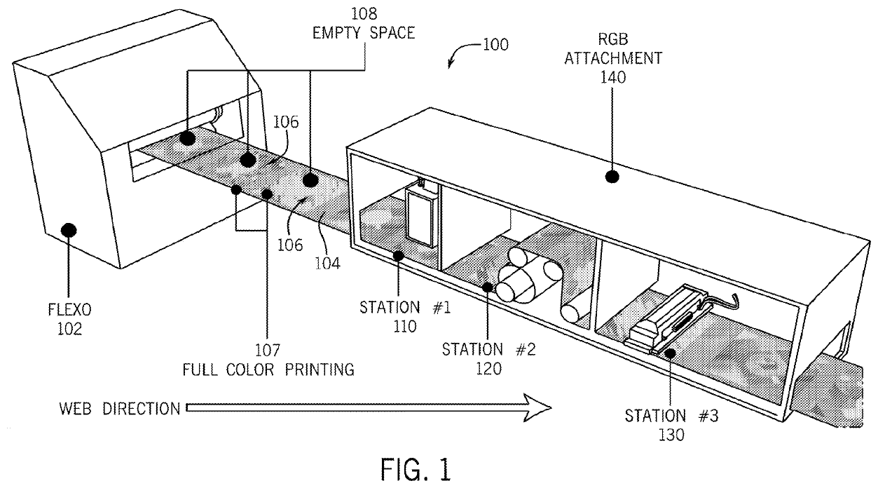

FIG. 1 illustrates a system 100 for generating variable optical images in curable material using generic optical matrices, in accordance with one or more implementations. In exemplary implementations, the system 100 may include equipment including, one or more of: an applicator, a transparent roller, a radiation source, an image generation component, and/or other components. The system may also include a printer 102, such as a flexographic printer or three-dimensional printer, and a web 104 supporting a substrate 106. Certain components of the system may be grouped into stations, or modules. For example, the first station 110 or first module may include the applicator. The second station 120 or second module may include the transparent roller. The third station 130 or third module may include the image generation component. Other components may be included within each of these stations or modules. The three stations 110, 120, 130 or modules may be adjacently coupled together and be in communication with each other, such that the web 104 or carrier is able to travel between the adjacent stations. The three stations 110, 120, 130 may be collectively referred to as an “RGB attachment” 140. The RGB attachment 140 may be configured to “plug and play” with many different types of printers 102 and be used in various print assemblies. The design and benefits of the modular system 100 described herein allows the RGB attachment 140 to be easily integrated into various applications for use with various products, which increases efficiencies and reduces costs.

The flexographic printer 102 may be configured to provide, or print, a substrate 106 supported by a web 104, or carrier. In one example, the substrate 106 may be a printed label on the carrier 104, such that the label may be removed from the carrier 104 and applied to another object. Other types of substrates 106 may be used. The substrate 106 may be one continuous piece of material or be a series of sections of material. Hereinafter, the term “substrate” may refer to a continuous piece of material or any of the individual sections of the series of substrate material. The substrate 106 may be provided by the flexographic printer 102 or digital printer in print cycles. Other types of printers and printing processes may be used, such as offset, digital, rotogravure, etc. The substrate 106 may include full color printing 107 on one portion of the substrate 106 and an empty space 108, or spaces, on another portion of the substrate 106. In this regard, the substrate 106 may include a printed portion 107 and a non-printed portion 108. In one example, the number, location, and design/layout of the printed 107 and non-printed 108 portions of the substrate 106 may vary between print cycles. In another example, every aspect of the substrate 106 may be the same between different print cycles. The flexographic printer 102 generates the substrate 106, and determines the number, location, and design/layout of the printed 107 and non-printed 108 portions, based on information provided to it (e.g., substrate specification data supplied to the printer 102). This information may be predetermined based on the desired final product of the optical image and substrate 106. In this regard, the printed 107 and/or the non-printed 108 portions may also be referred to as designated portions. For example, the non-printed portions 108 may be designated areas or portions where a desired optical image may be located. In this example, the printed portions 107 may be non-designated areas.

The web 104, or carrier, may be configured to support and carry/transport the substrate material 106 to the other various components of the system 100. As shown in FIG. 1, the flexographic printer 102 may be configured to provide the web 104 supporting the substrate 106 to the applicator in a web direction. In other words, the substrate 106 moves along the carrier 104 from a first direction to a second direction. In the figures, the first direction may be the left side of the figures and the second direction may be the right side of the figures. In this way, the carrier web 104 travels, and carries the substrate 106, from the flexographic printer 102 to the first station 110, from the first station 110 to the second station 120, and from the second station 120 to the third station 130, after which the web carrier 104 and substrate 106 with an optical image are output from the RGB attachment 140.

The optical image to be created or transferred to a substrate 106 may include a physical likeness or representation of a person, animal, and/or thing that is photographed, painted, and/or otherwise made visible or may be a negative of such images. The image may also be a code or variable code, as described in more detail below.

According to various implementations, the image may be in an electronic format, as discussed further herein. As such, a component of the system 100, such as an image component, may include electronic storage configured to store the image in an electronic format. In one example, the image component may be part of another component of the system 100, such as the image generation component, described below. In another example, the image component may be a separate component in communication with one or more other system components. The image component may include one or more processors configured to provide information associated with the image to one or more other components of system. The image may be based on a geometry associated with a matrix of surface elements on an outer surface of a roller, as described in more detail below.

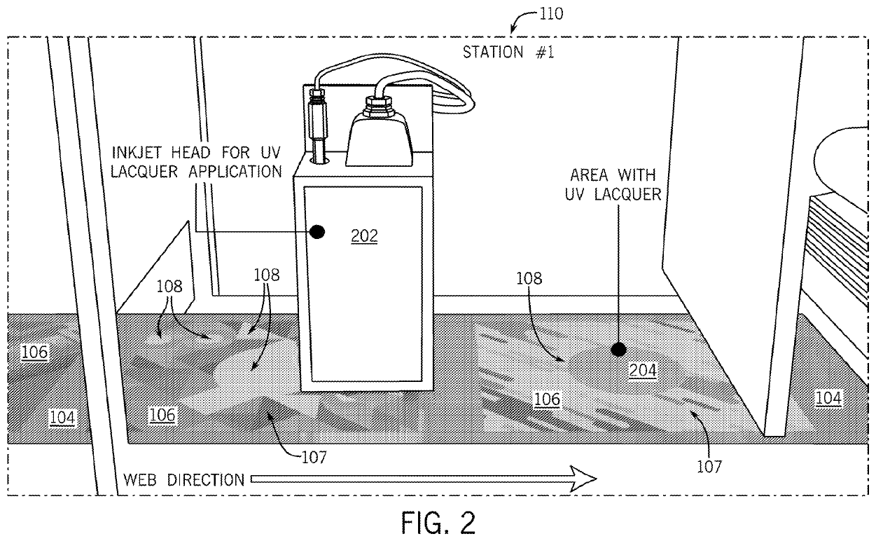

The system 100 may include, in the first station 110, an applicator 202 configured to apply a curable material 204 to a designated portion 108 of the substrate 106 supported by the carrier web 104. FIG. 2 illustrates a curable material 204 applied to a portion 108 of a substrate 106 by an applicator 202, in accordance with one or more implementations. In one example, the applicator 202 may be a printer 202 and may be configured to apply the curable material 204 to a designated portion 108 of the substrate 106. The printer 202 may be an inkjet printer with an inkjet head for UV lacquer application. In other implementations, flexographic printing may be used to apply the UV lacquer. In yet other embodiments, three-dimensional printers may be used. The designated 108 and non-designated 107 portions may be any size or shape on the substrate. As shown in FIG. 2, the designated or non-printed portions 108 of the substrate 106 on the left, where the applicator 202 is applying the curable material 204 to the substrate 106, includes a plurality of designated portions 108. For example, the section of substrate 106 on the left includes a centrally located designated portion 108 with a substantially circular shape with other geometric shapes (e.g., square and triangles) connected thereto. This section of substrate 106 also includes other designated portions 108 in smaller circular or semi-circular shapes spaced apart from the centrally located designated portion 108. The printed 107, or non-designated areas, also include geometric shapes. The section of substrate 106 on the right includes a centrally located circular designated portion 108 with UV lacquer 204 applied by the applicator 202. As shown in FIG. 2, the sections of substrates 106 pass through the first station 110 along the web direction (i.e., from the first direction to the second direction). As the substrates 106 pass through the first station 110, the applicator 202 applies the curable material 204 to the non-printed portion 108 of the substrate 106.

As mentioned above, the size, shape, and location of the designated 108 and non-designated 107 portion(s) may be based on information provided to the digital/ink jet head printer. Specifying a portion 108 of the substrate 106, which is separate from the printed portion 107 of the substrate, to receive the curable material 204 allows for greater flexibility and complexity to designs and patterns involving optical images using generic optical matrices. Rather than printing out entire sheets of substrates 106 containing optical images in curable material and then cutting out and incorporating those optical images into other designs, specifying only portions 108 of the substrate 106 to receive the curable material 204 reduces the amount of curable material 204 needed and allows optical images in curable material 204 to be implemented in a variety of underlying substrates 106 (e.g., labels, etc.). In this way, the disclosed system and method allows users to incorporate the unique optical images into their existing printing applications by simply utilizing the disclosed RGB attachment 140.

In one example, the curable material 204 may include a radiation curable material. The radiation curable material 204 may include one or more materials (e.g., liquid, gel, film, and/or other materials) that become cured when exposed to radiation. Examples of such radiation may include one or more of ultraviolet radiation, laser radiation, electron beam radiation, sunlight radiation, UV LED radiation, and/or other radiation. In some implementations, the radiation curable material 204 may include an embossable lacquer that is cured when exposed to ultraviolet light (i.e., UV lacquer). The curable material 204 may also be printable, similar to ink. In this regard, the curable material 204 is an embossable, printable, curable material. The radiation curable material 204 may be transparent when cured. The radiation curable material 204 may be colored when cured.

The system 100 may also include, in the second station 120, a transparent roller 302 including surface elements 304 formed on an outside surface of the transparent roller 302. The surface elements 304 may be microscopic or nanoscopic optical structures formed on the outside of the transparent roller 302. Other sized surface elements 304 are possible. In other implementations, the surface elements 304 may be formed in a transparent layer wrapped around the roller 302. In this case, the surface elements 304 may be formed into this separate layer (e.g., transparent shim or embossing plate) placed on top of the roller surface. This transparent shim or embossing plate may be made of a polymer, such as a plastic. The transparent roller 302 may be configured to form optical structures in the curable material 204. In other words, the surface elements 304 on the transparent roller 302 may form the optical structures in the curable material 204 when the surface elements 304 contact the curable material 204 as the substrate 106 travels over the outside surface of the transparent roller 320. The surface elements 304 of the transparent roller 302, which are also transparent and made of materials such as polymers or plastics, may form a surface relief pattern 306 and the optical structures on the curable material 204 may form a generic optical matrix corresponding to the surface relief pattern 306. In other words, the surface relief pattern 306 of the surface elements 304 is a negative of the generic optical matrix of the curable material 204.

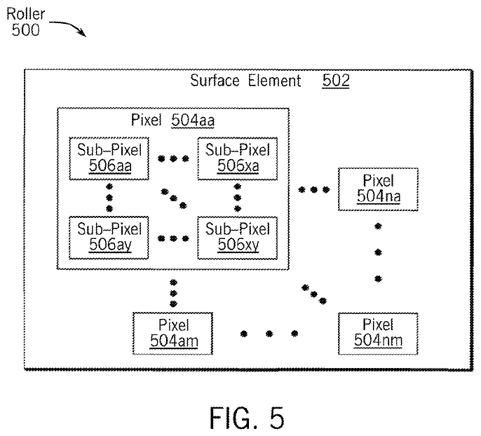

The optical structures formed in the curable material 204 include static physical optical pixels (referred to herein as either static physical optical pixels or simply static physical pixels), where some optical structures, or pixels, relate to the color red, some relate to the color green, and others relate to the color blue. Likewise, some sub-structures, or sub-pixels, relate to non-color effects, such as viewing angles. These static physical pixels are different than, for example, traditional LED pixels, that may relate to red, green, and blue, and change based on a particular input to the LED pixel. The static physical pixels, including sub-pixels, will be described below in more detail with regard to FIG. 5.

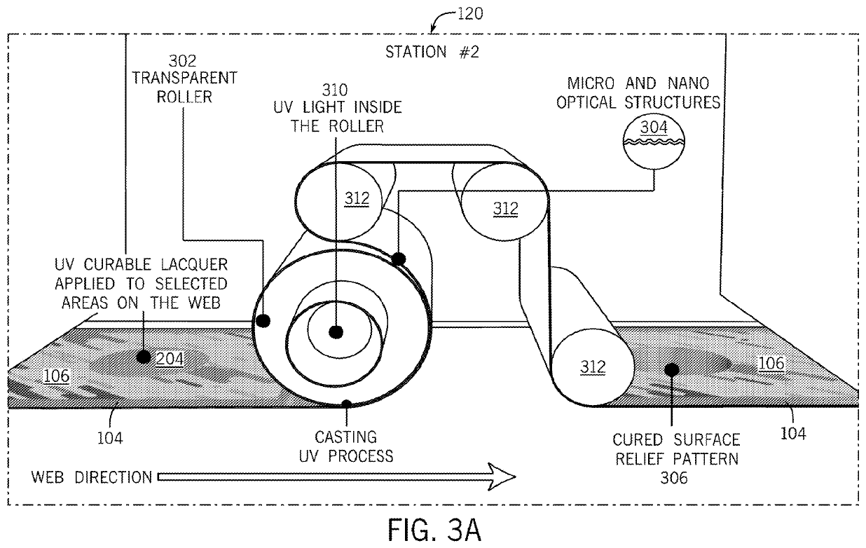

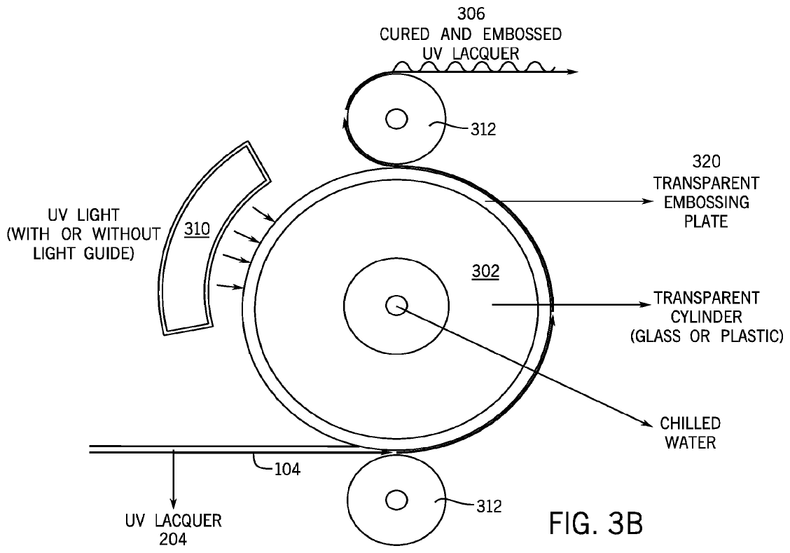

FIGS. 3A and 3B illustrate a cured surface relief pattern 306 on the substrate 106 after optical structures are formed in the curable material 204 by a transparent roller 302, in accordance with one or more implementations. As shown in FIGS. 3A and 3B, the substrate 106 containing the curable material 204 applied to selected areas 108 of the substrate 106 is shown on the left side of FIGS. 3A and 3B, as the substrate 106 travels along the carrier web 104 from the previous station—the first station 110 of FIG. 2—to the transparent roller 302 of the second station 120. As the carrier web 104 engages with and travels over the surface of the transparent roller 302, surface elements 304 on the outer surface of the roller 302 make contact with the curable material 204 and emboss, imprint, or otherwise form the surface relief pattern 306, in negative, into the curable material 204. In other words, the roller surface having the surface elements 304 strikes the embossable side of the substrate 106 in order to create the optical image or optical effect in the substrate 106. The surface elements 304 on the roller 302 contact the curable material 204 to form optical structures in the curable material 204, i.e., the curable material 204 is embossed, UV casted or imprinted by the roller 302. The optical structures include static physical optical pixels and form what is referred to as a generic optical matrix of microscopic or nanoscopic optical structures, described in more detail below. The generic optical matrix corresponds to the surface relief pattern 306 of the surface elements 304, since one is the negative of the other.

As shown in FIG. 3A, the transparent roller 302 includes a radiation source 310 centrally located within the roller 302. However, as shown in FIG. 3B, the radiation source 310 may be located outside of the transparent roller 302. The radiation source 310 may be configured to cure the curable material 204 after the optical structures are formed in the curable material 204. In one example, the radiation source 310 may be an ultraviolet light source 310, with or without light guide, as shown in FIGS. 3A and 3B. For instance, once the surface elements 304 of the roller 302 press into the curable material 204 toward the bottom of the roller 302 in FIGS. 3A and 3B and form the optical structures in the curable material 204, the carrier web 104 carries the substrate 106 and embossed, imprinted, or formed curable material 204 along the outer surface of the roller 302 in a counterclockwise direction until the carrier web 104 engages another roller 312. During this time, the radiation source 310 produces radiation that penetrates the transparent surface of the roller 302, such that the curable material 204 is exposed to the radiation source 310, the curable material 204 thus becoming cured as a result of being exposed to the radiation. The transparent roller 302 may be a transparent solid cylinder, a transparent hollow cylinder, or a transparent water filled cylinder, as shown in FIG. 3B.

In one example, the cured material (i.e., cured surface relief pattern 306 in the curable material 204) and underlying substrate 106 is then fed through a series of other rollers 312 in the web direction, as shown in FIGS. 3A and 3B, to exit the second station 120 and be fed into the third station 130, described below. At this stage, the substrate 106 contains the cured material having the generic optical matrix formed therein.

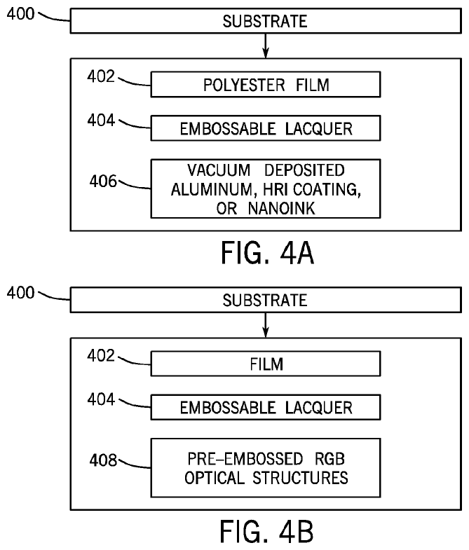

FIGS. 4A and 4B illustrate two examples of substrates 400 and layers that can be manufactured using with the components of the system of FIGS. 1-3. As shown, in FIG. 4A, the substrate 400 may include a polyester film 402, an embossable lacquer 404 (at least in some areas on the substrate 400) and a vacuum deposited aluminum, HRI coating, or nanoink (either metallic or HRI) 406 on the embossable lacquer 404. The embossable lacquer 404 is a lacquer in which a generic optical matrix can be created as discussed above. As shown in FIG. 4B, the substrate 400 may include a polyester film 402, an embossable lacquer 404 and one or more pre-embossed layers or coatings that have RGB optical structures 408 formed therein. The pre-embossed layers or coatings may be further embossable by the transparent roller 302, as described herein.

When a transparent roller's 302 surface elements 304 contact or are pressed onto the embossable layer or layers, the surface reliefs will form corresponding surface reliefs or optical reliefs in the substrate's embossable layer, e.g., embossable lacquer and/or aluminum or HRI coating, or both. This method of forming reliefs in an embossable material is sometimes commonly referred to as embossing or engraving. Other structures of the substrate and substrates with additional layers can be used as well, such as a substrate made of a soft material such as PVC, BOPP, OPP, which may be used with or without the aluminum deposit. The substrate may also have one or more layers or a coating of a pressure sensitive material and can be pre-die cut into different shapes before entering the disclosed system. This is useful, for example, for creating labels with variable optical images.

Another aspect of the disclosure includes a new roller surface for an embossing roller. The new roller surface has surface elements with specially designed surface reliefs, such as gratings, and can be used in an embossing roller apparatus, such as that described above with regard to FIGS. 3A and 3B. The surface elements may have optical pixels that may have resolutions between at least about 100 dots per inch (100 dpi) and 2400 dpi or more, which allows more advanced optical effects to be generated. The inside of these optical pixels may have resolutions between 50 to 200,000 dpi and may be made by different sorts of optical structures (e.g., nanostructures). Higher resolutions, such as increasing the optical pixel resolutions from 1200 to 2400 dpi, may be achieved by using or placing more than one roller or inkjet heads in tandem, e.g., two 1200 dpi rollers or inkjet heads placed in tandem can achieve 2400 dpi resolution on a curable embossable material. In another example, four 600 dpi rollers or inkjet heads may be placed in tandem to achieve 2400 dpi resolution. The roller 500, shown schematically in FIG. 5, can be used to create or replicate surface reliefs in an embossable, curable material that generates a generic optical matrix, which in turn allows for images with various optical and holographic effects.

FIG. 5 illustrates schematically a roller or roller surface 500 having a surface element 502. Of course, the roller surface 500 will have many surface elements 502, but only one is shown here for illustration purposes. The surface element 502 has optical structures formed by surface reliefs that form a matrix of static physical optical pixels 504 (hereinafter referred to simply as pixels 504) corresponding to color and static physical optical sub-pixels 506 (hereinafter referred to simply as sub-pixels 506) corresponding to non-color, in accordance with one or more implementations. The roller surface 500 may have a matrix of surface elements 502, each having surface reliefs that form optical structures that are pixels 504 and sub-pixels 506 etched into the roller's surface elements 502. Some optical structures are pixels 504 that have a geometry such that they correspond to color and some optical structures are sub-pixels 506 that have a geometry that correspond to non-color effects.

The pixels 504 may be disposed on the roller surface 500 as an array. The total number of pixels 504 in the array may depend on the size of the surface element 502. For example, low resolution may be used for creating three-dimensional posters that can be seen at a given distance (e.g., one meter, two meters, ten meters, fifty meters, and/or other distances). High resolution may be used for creating labels with micro- or nano-texts, hidden images, and/or other security features. According to various implementations, the number of pixels 504 in the array may be hundreds, thousands, millions or other quantities. The array of pixels 504 may have a resolution in the range of about 100 dpi to about 2400 dpi (or more). The array of pixels 504 may be arranged as one or more of a square lattice, a hexagonal lattice, triangular lattice, rectangular lattice, a random or pseudorandom arrangement, and/or other arrangements. Individual ones of pixels 504 may be shaped as a circle, a square, a rectangle, a line, an oval, a rounded square, dots, and/or other shapes.

Different pixels 504 may correspond to different colors. That is, some of pixels 504 may correspond to pixels that are configured to create corresponding surface reliefs/optical structures in an embossable material that reflect and/or transmit one color of light while other pixels 504 are configured to create corresponding surface reliefs/optical structures in an embossable material that may reflect and/or transmit another color of light. The color of a given pixel may depend on an angle at which the given pixel is viewed in the embossable material. For example, as a viewing angle changes, a color of light reflected or transmitted by the given pixel may change (e.g., by sweeping through the range of visible colors). In some implementations, the array may include first pixels 504 configured to create surface reliefs/optical structures in an embossable material corresponding to a first color and second pixels 504 configured to create surface reliefs/optical structures in an embossable material corresponding to a second color. The first color may be different from the second color. The array may further include third pixels 504 configured to create surface reliefs/optical structures in an embossable material corresponding to a third color. The third color may be different from the first color and the second color. In some implementations, the array may further include fourth pixels 504 are configured to create surface reliefs/optical structures in an embossable material corresponding to a fourth color. The fourth color may be different from the first color, the second color, and the third color. In sum, the array may include pixels corresponding to any number of different colors. According to some implementations in which the color scheme is binary, the first and second pixels 504 may respectively correspond to blue and red (or other colors). In some implementations in which the color scheme is ternary (e.g., RGB), the first, second, and third pixels 504 may respectively correspond to red, green, and blue (or other colors). In some implementations in which the color scheme is quaternion (e.g., CMYK), the first, second, third, and fourth pixels 504 may respectively correspond to cyan, magenta, yellow, and black (or other colors). Although certain color schemes are described above, it will be appreciated that other color schemes are contemplated and are within the scope of the disclosure.

In the array, pixels 504 may be arranged in a motif of static physical pixels. Generally speaking, a motif may describe a distinctive and recurring pattern. According to some implementations, first pixels 504 and second pixels 504 may be arranged in a motif such that individual ones of first pixels 504 are positioned adjacent to individual ones of second pixels 104. In implementations having third pixels 504, they may be arranged in the motif such that individual ones of third pixels 504 are positioned adjacent to individual ones of first pixels 504 and individual ones of second pixels 504. In implementations having fourth pixels 504, they may be arranged in the motif such that individual ones of fourth pixels 504 are positioned adjacent to individual ones of first pixels 504, individual ones of second pixels 504, and individual ones of third pixels 104. In some implementations, similar pixels may not be positioned adjacent to each other (e.g., no two first pixels positioned adjacent to each other). Although pixels 504 may be arranged in a motif, as discussed above, this should not be viewed as limiting as other arrangements are contemplated and are within the scope of the disclosure. For example, pixels 504 may be arranged randomly in the array. As another example, multiple different motifs may be used such that pixels 504 in some areas of the array are arranged in a first motif and pixels 504 in other areas of the array are arranged in a second motif.

Individual optical structures of sub-pixels 506 may be configured (and/or physically structured) to create corresponding surface reliefs/optical structures in an embossable material that reflect and/or transmit light meeting one or more conditions. For example, a given pixel 504 may include a first sub-pixel 506 and a second sub-pixel 506. The first sub-pixel 506 may include an optical structure configured to create surface reliefs/optical structures in an embossable material that reflect and/or transmit light meeting a first condition. The second sub-pixel 506 may include an optical structure configured to create surface reliefs/optical structures in an embossable material that reflect and/or transmit light meeting a second condition. The first condition may be different from the second condition. The light reflected and/or transmitted by surface reliefs formed in an embossable material by the first sub-pixel 506 and the second sub-pixel 506 may be the corresponding color of the given pixel 504. The given pixel 504 may include a third sub-pixel 106 and a fourth sub-pixel 506. The third sub-pixel 506 may include an optical structure configured to create surface reliefs/optical structures in an embossable material that reflect and/or transmit light meeting a third condition. The fourth sub-pixel 506 may include an optical structure configured to create surface reliefs/optical structures in an embossable material that reflect and/or transmit light meeting a fourth condition. The light reflected and/or transmitted by the surface reliefs/optical structures created in an embossable material that third sub-pixel 506 and the fourth sub-pixel 506 being the corresponding color of the given pixel 506. The third condition may be different from the first condition, the second condition, and the fourth condition. While only four conditions are described here, in some implementations, there may be any number of conditions.

The conditions associated with reflection and/or transmission may include conditions related to one or more of viewing angle, viewing distance, polarization, intensity, scattering, refractive index, birefringence, and/or other conditions. Continuing the example in the above paragraph, the first condition and the second condition may relate to a first viewing angle. The first condition may be that the light reflected or transmitted by the optical structure of the first sub-pixel 506 is directed toward a left eye of a person observing the substrate carrying the embossable material from the first viewing angle. The second condition may be that the light reflected or transmitted by the optical structure of the second sub-pixel 506 is directed toward a right eye of the person observing the substrate carrying the embossable material from the first viewing angle. The third condition and the fourth condition may relate to a second viewing angle. The third condition may be that the light reflected or transmitted by the optical structure of the third sub-pixel 506 is directed toward the left eye of the person observing substrate carrying the embossable material from the second viewing angle. The fourth condition may be that the light reflected or transmitted by the optical structure of the fourth sub-pixel 506 is directed toward a right eye of the person observing substrate carrying the embossable material from the second viewing angle. The first viewing angle may be different from the second viewing angle.

Referring again to FIG. 1, the image generation component may form an optical image in the cured material having the generic optical matrix. The generic optical matrix may be formed by the surface reliefs/surface elements of the roller surface that form optical structures in the embossable, curable material. The optical image may be created by obliterating certain desired surface reliefs/optical structures formed in the embossed, cured material on the substrate, leaving only certain desired other surface reliefs/optical structures that reflect or transmit light. The optical image may exhibit non-color effects corresponding to other surface reliefs/optical structures formed in the embossed, cured material on the substrate. The non-color effects may give rise to one or more optical effects observable when viewing the optical image. The one or more optical effects may include one or more of a three-dimensional optical effect, a two-dimensional optical effect, a dynamic optical effect, a scattering effect, a holographic white effect, a lens effect, a Fresnel lens effect, a brightness modulation effect, a lithographic effect, a stereogram effect, a nanotext and/or microtext effect, a hidden image effect, a moire effect, a concealed animated pattern effect, a covert laser readable (CLR) effect, a multiple background effect, a pearlescent effect, a true color image effect, a guilloche effect, an animation effect, an achromatic Fresnel effect, a dynamic CLR image, a kinematic images, a full parallax effect, a scratch holographic effect, a polarizing effect, a watermark effect, a metallic effect, a binary optical structure, a Fresnel prism, different viewing distances effect, any rainbow effect, structural colors effects and/or other optical effects.

Individual ones of the sub-pixels formed in the embossed, cured material may reflect light at a specific viewing angle with a color. According to some implementations, the optical image may comprise one or more of a hologram, a stereo image, an optically variable device (OVD) based image, a diffractive optically variable image, a zero order device (ZOD) based image, a blazed diffraction structure based image, a first order device (FOZ) based image, a dot matrix image, a pixelgram image, a structural color structure based image, a diffractive identification device (DID) based image, an interference security image structure (ISIS) based image, a kinegram image, an excelgram image, a diffractive optical element based image, a photonic structure based image, a nanohole based image, computer generated holograms, electron-beam generated optical structures, interference patterns, metasurface holograms, plasmonic holograms, tensor holograms, voxel type holograms, quantum holograms, light field holograms, artificial intelligent holograms, structural color structures, lithographic deep structures, and/or other optical images.

According to some implementations, a person may view the optical image in the embossed, cured material from a specific viewpoint or viewing window (e.g., a range of viewing angles and/or distances). By changing the viewpoint or viewing window (e.g., by moving the optical image relative to the person's eyes), observed colors of the optical image may change due to the reflective properties of the optical structures included in the optical image. The viewpoint or viewing window may be limited in implementations where only the optical structures provide color in the optical image. In order to avoid such a limitation, the optical image may be overprinted with specific colors at corresponding pixels and/or sub-pixels. For example, if the optical image includes two sub-pixels to be viewed as red-one for the right eye and one for the left eye, the viewpoint or viewing window may be relatively small. However, by overprinting those two sub-pixels with a translucent red colored ink, the viewpoint or viewing window may increase because this colored ink maintains the red color with no shift through the rainbow and optical structures of the two sub-pixels keep reflecting light to desired directions. In some implementations, high refractive index lacquers may be used for the purpose of being able to overprint on top with translucent inks and/or lacquers without obliterating pixels and/or sub-pixels. Thus, some implementations may provide optical images having pixels and/or sub-pixels that reflect their particular color but shift throughout the rainbow at different angles, or have a colored filter that helps them extend the viewpoint or viewing window.

In some implementations, the index of refraction of a material making up the optical structures of sub-pixels formed in the embossed, cured material may be between approximately 1.4 and approximately 1.6. In some implementations, the high refractive index may be between approximately 1.75 and approximately 2. The high refractive index may be greater than 2.

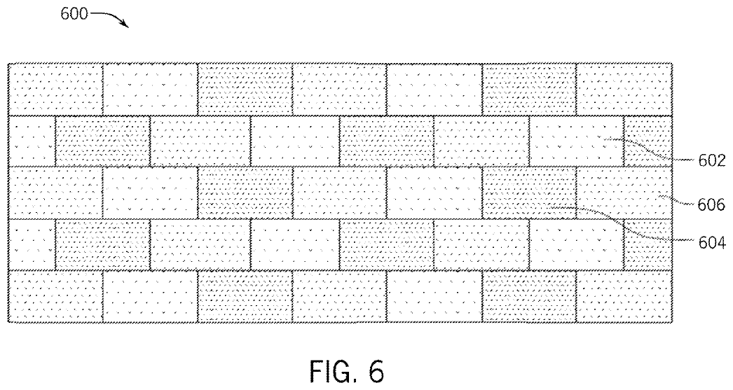

FIG. 6 illustrates an exemplary array 600 of pixels in a surface element 502, in accordance with one or more implementations. As depicted in FIG. 6, array 600 may include pixels corresponding to three different colors. Pixels similar to pixel 602 may correspond to a first color, pixels similar to pixel 604 may correspond to a second color, and pixels similar to pixel 606 may correspond to a third color. Pixels similar to pixel 602, pixels similar to pixel 604, and pixels similar to pixel 606 may be respectively arranged in superimposed hexagonal lattices such that a given pixel is adjacent to pixels of different colors and pixels of a common color are evenly distributed across array 600.

Referring again to FIG. 5, a given pixel 504 may include two or more sub-pixels 506. The sub-pixels 506 may be arranged within a given pixel 504 as one or more of a square lattice, a hexagonal lattice, triangular lattice, rectangular lattice, random or pseudorandom arrangement, and/or other arrangements. Individual ones of sub-pixels 506 may be shaped as a circle, a square, a rectangle, a line, an oval, a rounded square, dots, spirals, patterns, and/or other shapes.

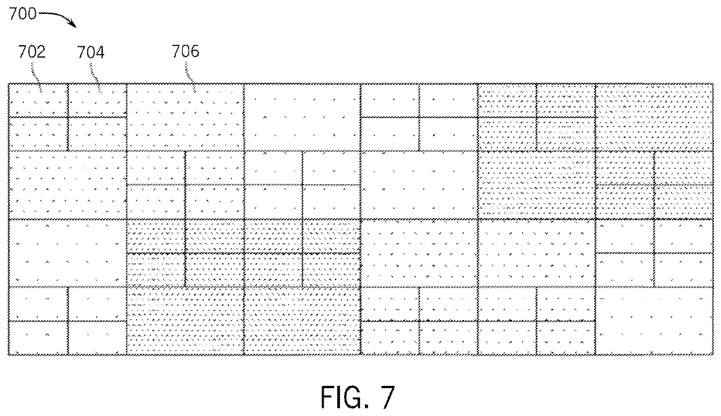

FIG. 7 illustrates an exemplary array 700 of pixels with sub-pixels, in accordance with one or more implementations. As depicted in FIG. 7, a given pixel may include one or more of sub-pixel 702, sub-pixel 704, sub-pixel 706, and/or other sub-pixels. The sub-pixel 702, sub-pixel 704, and/or sub-pixel 706 may be similar or different with respect to optical characteristics and/or physical characteristics. Examples of optical characteristics may include one or more of reflectivity, transmissivity, absorptivity, and/or other optical characteristics. Examples of physical characteristics may include size, shape, and/or other physical characteristics.

Turning again to FIG. 5, individual ones of sub-pixels 506 may correspond to non-color effects. The non-color effects may result from optical characteristics and/or physical characteristics of individual ones of sub-pixels 506. Such non-color effects may be achieved by optical structures included in sub-pixels 506. An optical structure of a given sub-pixel 506 may include one or more of a ruled grating, a laser grating, a photonic grating, an e-beam grating, an ion beam grating, gratings created by nanoholes, a hologram, a three-dimensional nano-structure, a kinegram, a photonic structure, a Fresnel lens, an electron-beam grid, an exelgram, an optical variable device (OVD), a diffractive optically variable image device (DOVID), a zero order device, a pixelgram (e.g., as provided by CSIRO of Australia), a holographic stereogram, a diffraction identification device (DID), a dielectric structure, a volume hologram, a liquid crystal, an interference security image structure (ISIS), a computer-generated hologram, an electron-beam grating, a metasurface hologram, a plasmonic hologram, a tensor hologram, a voxel type hologram, a quantum hologram, a light field hologram, an artificial intelligent hologram, structural color structures, lithographic deep structures and/or other optical structures. In some implementations, a given optical structure may include a physical feature having a linear dimension in the range of 0.01 microns to 1000 microns. For example, a given pixel may be composed of lithographic structures having depths in the range of 0.2 microns to 100 microns. In some implementations, optical structures of sub-pixels 506 of a given pixel 504 may be configured such that some reflections/transmissions go to the right eye of a person viewing the embossed, cured material and other reflections/transmissions go to the left eye.

Individual optical structures of sub-pixels 506 may be configured (and/or physically structured) to reflect and/or transmit light meeting one or more conditions. For example, a given pixel 504 may include a first sub-pixel 506 and a second sub-pixel 506. The first sub-pixel 506 may include an optical structure configured to reflect and/or transmit light meeting a first condition. The second sub-pixel 506 may include an optical structure configured to reflect and/or transmit light meeting a second condition. The first condition may be different from the second condition. The light reflected and/or transmitted by the first sub-pixel 506 and the second sub-pixel 506 may be the corresponding color of the given pixel 504. The given pixel 504 may include a third sub-pixel 506 and a fourth sub-pixel 506. The third sub-pixel 506 may include an optical structure configured to reflect and/or transmit light meeting a third condition. The fourth sub-pixel 506 may include an optical structure configured to reflect and/or transmit light meeting a fourth condition. The light reflected and/or transmitted by the third sub-pixel 506 and the fourth sub-pixel 506 being the corresponding color of the given pixel 506. The third condition may be different from the first condition, the second condition, and the fourth condition. While only four conditions are described here, in some implementations, there may be any number of conditions.

The conditions associated with reflection and/or transmission may include conditions related to one or more of viewing angle, viewing distance, polarization, intensity, scattering, refractive index, birefringence, and/or other conditions. Continuing the example in the above paragraph, the first condition and the second condition may relate to a first viewing angle. The first condition may be that the light reflected or transmitted by the optical structure of the embossed, cured material with the optical image from the first viewing angle. The second condition may be that the light reflected or transmitted by the optical structure of the second sub-pixel 506 is directed toward a right eye of the person observing the embossed, cured material from the first viewing angle. The third condition and the fourth condition may relate to a second viewing angle. The third condition may be that the light reflected or transmitted by the optical structure of the third sub-pixel 506 is directed toward the left eye of the person observing embossed, cured material from the second viewing angle. The fourth condition may be that the light reflected or transmitted by the optical structure of the fourth sub-pixel 506 is directed toward a right eye of the person observing embossed, cured material from the second viewing angle. The first viewing angle may be different from the second viewing angle.

Continuing the example in the above paragraph, the first condition and the second condition may relate to a first viewing distance. The first condition may be that the light reflected or transmitted by the optical structure of the first sub-pixel 506 is directed toward the left eye of the person observing embossed, cured material from the first viewing distance. The second condition may be that the light reflected or transmitted by the optical structure of the second sub-pixel 506 is directed toward the right eye of the person observing the embossed, cured material from the first viewing distance. The third condition and the fourth condition may relate to a second viewing distance. The third condition may be that the light reflected or transmitted by the optical structure of the third sub-pixel 506 is directed toward the left eye of the person observing embossed, cured material from the second viewing distance. The fourth condition may be that the light reflected or transmitted by the optical structure of the fourth sub-pixel 506 is directed toward the right eye of the person observing the embossed, cured material from the second viewing distance. The first viewing distance may be different from the second viewing distance. In some implementations, images may be created in the embossed, cured material that are viewable with only one eye (or viewpoint) such as for dynamic optical effects.

Still continuing the example in the above paragraph, the first condition and the second condition may relate to polarization. The first condition may be that the light reflected or transmitted by the optical structure of the first sub-pixel 506 has a first polarization. The second condition may be that the light reflected or transmitted by the optical structure of the second sub-pixel 506 has a second polarization. The first polarization may be different from the second polarization.

The pixels 504 may include first pixels 504aa corresponding to a first color and second pixels 504na corresponding to a second color. The sub-pixels 506 may include first sub-pixels 506aa corresponding to a first non-color effect and second sub-pixels 506xa corresponding to a second non-color effect. The geometry is known and the one or more physical processors may be configured by machine-readable instruction to send instructions to the image generation component such that the pixels 504 and sub-pixels 506 create desired surface reliefs in desired locations on the embossed, cured material.

In this manner, the roller surface pixels 504 and/or sub-pixels 506 may be selectively used to create surface reliefs/optical structures on an embossable, curable material to form a generic optical matrix used to generate an optical image corresponding to a base image in an image generation device. The optical image may exhibit different colors corresponding to the pixels 504 and may exhibit non-color effects corresponding to the sub-pixels 506. The non-color effects of the sub-pixels may give rise to one or more optical effects observable when viewing the optical image in the embossed, cured material. The one or more optical effects may include one or more of a three-dimensional optical effect, a two-dimensional optical effect, a dynamic optical effect, a scattering effect, a holographic white effect, a lens effect, a Fresnel lens effect, a brightness modulation effect, a lithographic effect, a stereogram effect, a nanotext and/or microtext effect, a hidden image effect, a moire effect, a concealed animated pattern effect, a covert laser readable (CLR) effect, a multiple background effect, a pearlescent effect, a true color image effect, a guilloche effect, an animation effect, an achromatic Fresnel effect, a dynamic CLR image, a kinematic images, a full parallax effect, a scratch holographic effect, a specular effect, a polarizing effect, a watermark effect, a metallic effect, a binary optical structure, a Fresnel prism, different viewing distances effect, any rainbow effect, structural colors effects, lithographic effects and/or other optical effects.

Individual ones of the sub-pixels 506 in the surface element 502 may create surface reliefs/optical structures in the embossable, curable material that reflect light at a specific viewing angle with a color corresponding to that of the individual pixels associated with the sub-pixels in the roller surface.

According to some implementations, the optical image may comprise one or more of a hologram, a stereo image, an optically variable device (OVD) based image, a diffractive optically variable image, a zero order device (ZOD) based image, a blazed diffraction structure based image, a first order device (FOZ) based image, a dot matrix image, a pixelgram image, a structural color structure based image, a diffractive identification device (DID) based image, an interference security image structure (ISIS) based image, a kinegram image, an excelgram image, a diffractive optical element based image, a photonic structure based image, a nanohole based image, computer generated holograms, electron-beam generated optical structures, interference patterns, specular and scratch patterns, moire images, light field images, metasurface holograms, plasmonic holograms, tensor holograms, voxel type holograms, quantum holograms, light field holograms, artificial intelligent holograms and structural color structures, lithographic structures, and/or other optical images.

According to some implementations, a person may view the optical image from a specific viewpoint or viewing window (e.g., a range of viewing angles and/or distances). By changing the viewpoint or viewing window (e.g., by moving the optical image relative to the person's eyes), observed colors of the optical image may change due to the reflective properties of the optical structures included in the optical image. The viewpoint or viewing window may be limited in implementations where only the optical structures provide color in the optical image.

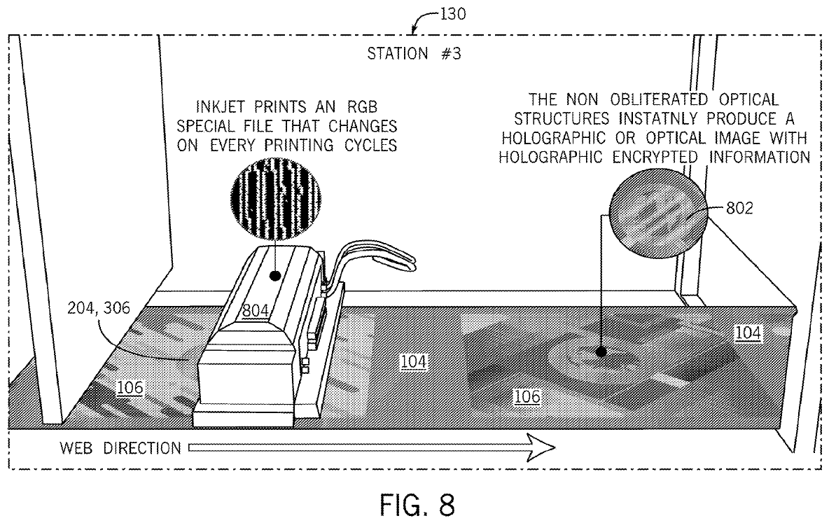

Referring now to FIG. 8, an image 802 formed in the cured material on the substrate 106 by an inkjet printer 804 is shown, in accordance with one or more implementations. As the carrier web 104 carrying the cured material (i.e., cured surface relief pattern 306 in the curable material 204) on the substrate 106 enters the third station 130 from the second station 120 in the web direction, the cured material on the substrate 106 passes under or through the image generation component 804, which, in the example shown in FIG. 8, is an inkjet printer 804. The image generation component 804, or obliteration device, may be configured to obliterate portions of the optical structures of the generic optical matrix on the cured material to form a predetermined image 802. Obliterating in this sense means to remove, erase, or otherwise render inoperable, the optical structures (i.e., pixels and/or sub-pixels). By obliterating specific optical structures of the generic optical matrix, an image 802 may be formed. In other words, the generic optical matrix may be used in conjunction with the image generation component 804 to selectively obliterate certain pixels and/or sub-pixels while preserving remaining pixels and/or sub-pixels to instantly create an optical image 802. The non-obliterated, or remaining, optical structures (pixels and/or sub-pixels) are what form the holographic or optical image 802. In some implementations, the predetermined image 802 may include a holographic image, and the non-obliterated portions of the optical structures form the holographic image. In some examples, the holographic image may include encrypted information.

In one example, the image generation component 804 may be configured to obliterate certain portions of the optical structures based on digital information received by the image generation component 804, where the digital information identifies which portions of the optical structures to obliterate in the cured material. In other words, a holographic image may be formed in the cured UV material by obliterating certain optical structures (pixels/subpixels) according to digital information about a desired image sent to the third station 130. In this example, the digital information is used to identify which optical structures to obliterate in the cured UV material in order to create the desired holographic image 802.

In some implementations, the image generation component 804 may be configured to obliterate the portions of the optical structures by laser ablating portions of the optical structures. In one example, an array of lasers may be used to obliterate specific optical structures. In another example, an expanded laser beam (i.e., laser beam having an expanded or larger diameter) may be used that radiates through an opening (or specific designated openings) in a mask to target a larger surface area (i.e., the entire area of the mask), such that more portions of the optical structures may be obliterated in one pass. These enhanced laser systems improve upon the conventional dot-by-dot obliteration techniques. In other implementations, the image generation component 804 may be configured to obliterate the portions of the optical structures by printing ink or otherwise depositing pigment over portions of the optical structures with an inkjet printer. In yet other implementations, optical structures may be obliterated by chemical etching, using a thermal head of a thermal printer, and/or other techniques.

However, some of these obliterating techniques have drawbacks. For example, when obliterating by printing ink or depositing pigment, precision becomes a problem, since the ink and/or pigment tends to bleed. This results in certain optical structures being obliterated unnecessarily, which may lead to an undesired optical image or hologram. Obliterating by a single laser beam or an array of separate laser beams may be bulky, inefficient, too expensive and cost prohibitive. Therefore, there is a need for an improved method of obliterating desired optical structures in a generic optical matrix.

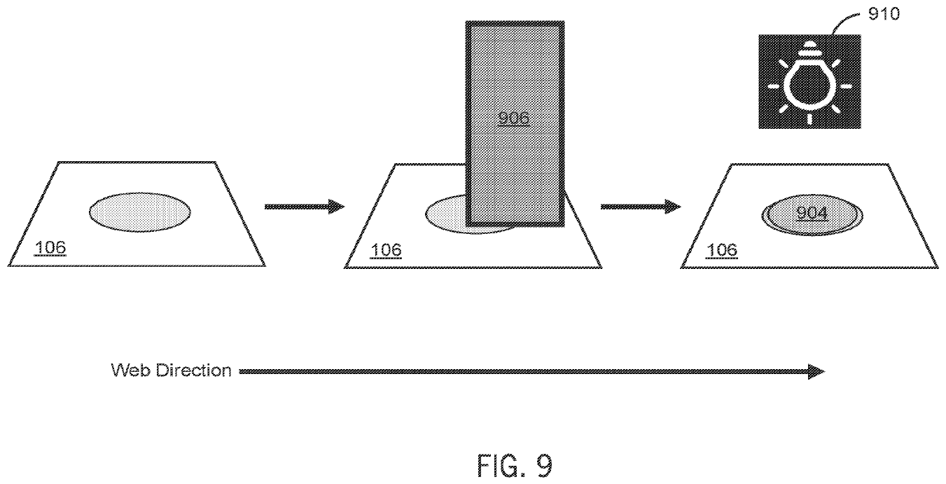

FIG. 9 illustrates schematically an exemplary image formed in the cured material on the substrate 106 by one or more image generation components, in accordance with one or more implementations. FIG. 9 depicts an alternative obliteration method to those discussed above. As will be described in more detail below, certain optical structures (pixels/sub-pixels) may be obliterated by applying another, or additional, curable material 904 on top of the previously cured material and curing the additional material 904 to change the color of certain optical structures (pixels/sub-pixels) so as to be non-functional. In one example, these steps are performed on the previously cured material on top of the substrate 106 that came from the second station 120. In another example, the disclosed novel method of obliterating by curing may be performed on any previously made substrate containing a generic optical matrix. In this way, the methods, devices, and systems discussed herein with the respect to at least FIGS. 9-12 may be a stand-alone system operable to be implemented in various printing processes and applications, such as desktop printers, etc.

In one example, to obliterate the portions of the optical structures, an image generation component 906 may be configured to apply another curable material 904 to the portion of the substrate 106, such that the other curable material 904 covers the optical structures. The image generation component 906 may also be configured to cure portions of the other curable material 904 corresponding to the portions of the optical structures to be obliterated, such that the cured portions of the other curable material 904 prevent the corresponding portions of the optical structures to reflect light. In some implementations, the image generation component 906 may be a single component capable of performing both of these steps. In other implementations, such as that shown in FIG. 9, the image generation component 906 may be comprised of one or more image generation components.

Referring back to FIG. 9, as the substrate 106 carrying the cured material containing the generic optical matrix travels along the web direction, an image generation component 906 applies an additional layer of curable material 904 to the already cured material, or to cover any portion of the substrate 106 containing the generic optical matrix. The image generation component 906 shown in FIG. 9 may be the same as the applicator 202 shown and described with respect to FIG. 2 above. Other types of applicators are possible.

The additional curable material 904 may be similar to the curable material 204 described above. For example, the additional curable material 904 may be similar to an ink that is applied similar to how ink is printed. The additional curable material 904 may also be transparent, but operable to change colors once cured. For example, the additional curable material 904 may be cured at different wavelengths and/or exposure times to change the color/transparency of the material (e.g., black (or color dark enough to prevent the optical structure from reflecting or transmitting light) or transparent). In another example, different intensity or strength of the light source 910 may lead to curing to different colors in the same way as different wavelengths and exposure times. In this regard, the image generation component 906 may be configured to cure the portions of the other curable material 904 at different wavelengths, at different exposure times, at different intensities, or a combination thereof to cure the other curable material 904 to different colors. Any now known or later developed inks or materials may be used as the additional curable material 904. For example, photochromic or photochromatic inks or dyes, which change color when exposed to certain light, may be used. In another example, nanoinks may be used to coat generated images in order to make them metallized or highly reflective with high diffractive index nanoinks.

In one example, after receiving the additional curable material 904, the additional curable material 904, or at least portions thereof, may be cured or semi-cured to stabilize the additional curable material 904. At this point, the additional curable material 904 would remain the same color as applied (e.g., clear), but will not bleed from the area it was applied. This curing or semi-curing step may depend on the type of additional curable material 904 used, as well as the specific wavelengths, light/radiation intensities and/or exposure times used.

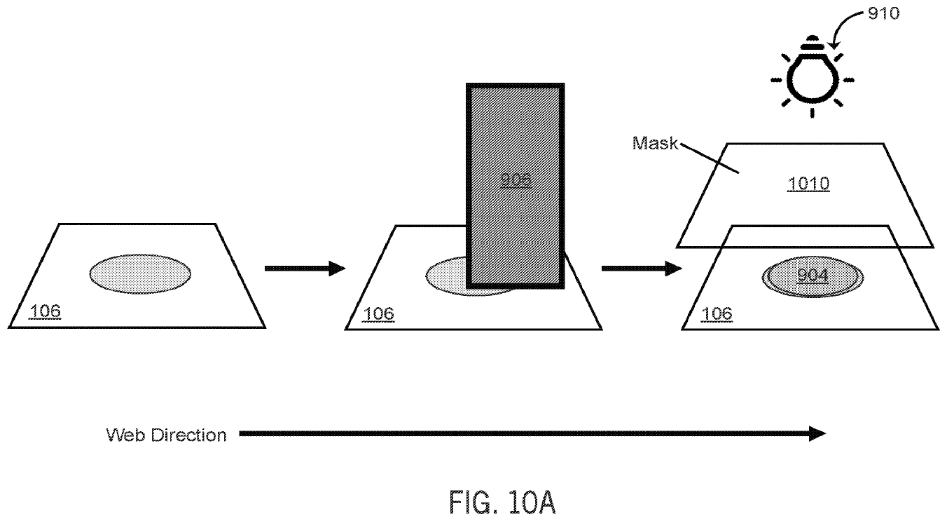

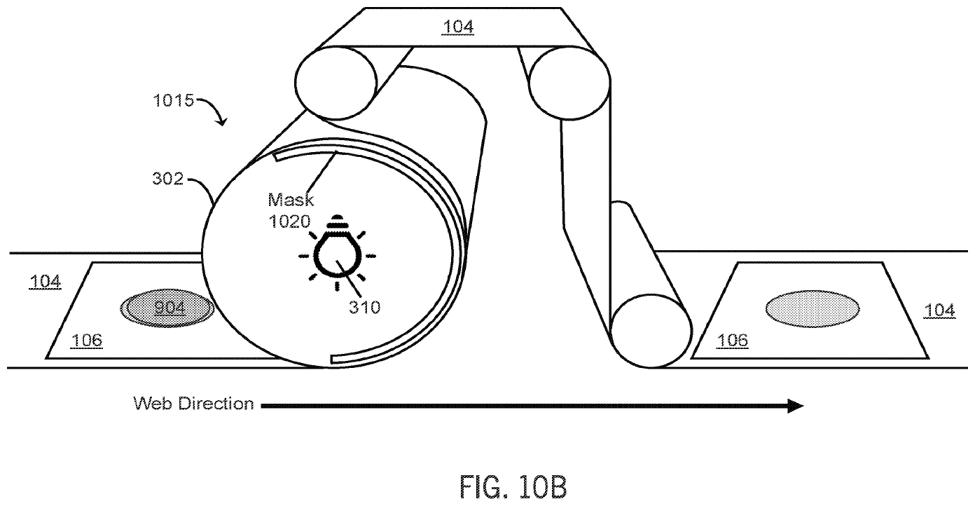

Next, the image generation component 906, or another component, may cure or additionally cure portions of the other curable material 904 at different wavelengths, at different exposure times and intensity (of the light source 910), or a combination thereof, in a number of ways. In one example, to cure at different wavelengths, at different exposure times, at different intensities, or a combination thereof, the image generation component 906 may be configured to cure through a mask. FIG. 10A illustrates schematically a mask 1010 used to generate an exemplary image formed in the cured additional material 904 on the substrate 106 by one or more image generation components 906, in accordance with one or more implementations. In the example shown in FIG. 10A, the mask 1010 may be positioned between a radiation (light) source 910 and the substrate 106 containing the additional curable material 904. The mask 1010 may be operable to allow light or radiation to pass through at specific areas, thereby exposing only certain portions of the additional curable material 904 below to the radiation. Those portions of the additional curable material 904 exposed to the radiation that passes through the mask 1010 become cured and change color in response to the radiation/light exposure. The color may be changed to black or a color dark enough to prevent the underlying optical structure(s) from reflecting or transmitting light (i.e., to render them inoperable). In some implementations, the mask 1010 may include a screen configured to change at a predetermined frequency. In one example, the predetermined frequency may be every print cycle. In some implementations, the screen may include a liquid crystal display (LCD) screen. In the case of an LCD screen/mask, rather than the mask 1010 acting as a physical block (i.e., negative of the desired image) that blocks radiation/light from a separate source, the LCD screen/mask may simply generate certain types of light from predetermined LCD pixels, where the operational LCD pixels essentially correspond to a negative of the desired optical image. In cases where the LCD screen/mask generates its own light source, a separate light/radiation source 910, such as that shown in FIG. 10A, may not be needed. In other examples, the mask 1010 may be a transparent display.

Other types of masks 1010 may be used. FIG. 10B illustrates schematically another mask 1020 used to generate an exemplary image formed in the cured additional material 904 on the substrate 106 by one or more image generation components 906, in accordance with one or more implementations. As shown in FIG. 10B, once the additional curable material 904 is applied to the specified portion of the substrate 106 to cover the generic optical matrix, the substrate 106 is fed into a roller system 1015. The roller system 1015 may include a transparent roller 302 having an internal light/radiation source 310. The roller system 1015 and transparent roller 302 of FIG. 10B may be the same or similar to the roller system and transparent roller 302 depicted and described in reference to FIGS. 3A and 3B above. As shown in FIG. 10B, the transparent roller 302 also includes a mask 1020. The mask 1020 may be positioned along an inside surface of the transparent roller 302, as shown in FIG. 10B, or along the outside surface of the transparent roller 302. In some implementations, the mask 1020 may be flexible. In other implementations, the mask 1020 may be rigid and shaped to correspond to either the inner or outer surface of the transparent roller 302. As shown in FIG. 10B, the mask 1020 may only be sized to correspond to a portion of the roller 302 (i.e., disposed along half of the inner/outer surface of the roller 302). In other examples, the mask 1020 may extend around the entire surface of the roller 302 (i.e., all the way around the inner/outer surface of the roller 302). In some examples, the mask 1020 may be stationary relative to the roller 302. In other examples, the mask 1020 may rotate along with the roller 302. Similar to the mask 1010 described above with regard to FIG. 10A, the mask 1020 of FIG. 10B may be positioned between a radiation (light) source 310 (in this case within the transparent roller 302) and the substrate 106 containing the additional curable material 904, which travels over the outside surface of the transparent roller 302. The mask 1020 may be operable to allow light or radiation to pass through the mask 1020 at specific areas, thereby exposing only certain portions of the additional curable material 904 (that is passing over the outer surface of the transparent roller 302) to the radiation. Those portions of the additional curable material 904 exposed to the radiation that passes through the mask 1020 become cured and change color in response to the radiation/light exposure. The color may be changed to black or a color dark enough to prevent the underlying optical structure(s) from reflecting or transmitting light (i.e., to render them inoperable).

In some implementations, the mask 1020 may include a screen configured to change at a predetermined frequency. In one example, the predetermined frequency may be every print cycle. In some implementations, the screen may include a liquid crystal display (LCD) screen. For instance, the mask 1020 may be a flexible LCD screen positioned at or near the inner or outer surface of the transparent roller 302. Similar to the LCD screen discussed above with respect to FIG. 10A, in the case of an LCD screen/mask, rather than the mask acting as a physical block (i.e., negative of the desired image) that blocks radiation/light from a separate source, the LCD screen/mask may simply generate certain types of light from predetermined LCD pixels, where the operational LCD pixels essentially correspond to a negative of the desired optical image. In cases where the LCD screen/mask generates its own light source, a separate light/radiation source 310, such as that shown in FIG. 10B, may not be needed.

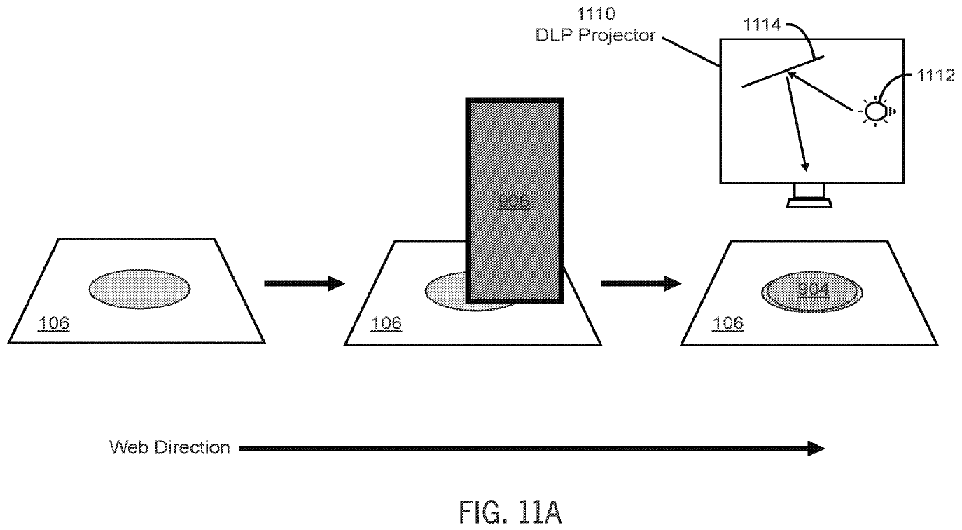

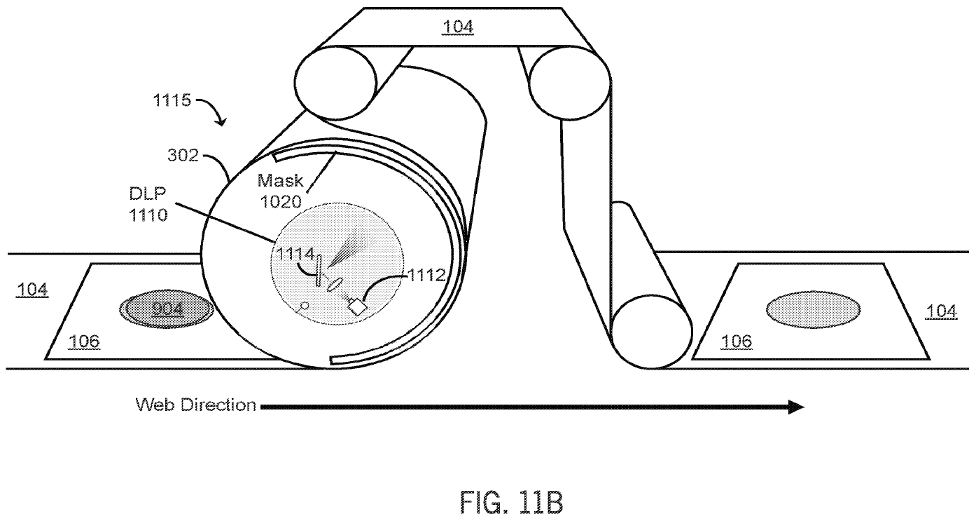

In another example, to cure at different wavelengths, at different exposure times, at different intensities, or a combination thereof, the image generation component 906 may be configured to cure using a digital light processor (DLP) projector. FIG. 11A illustrates schematically a DLP projector 1110 used to generate an exemplary image formed in the cured material on the substrate 106 by one or more image generation components 906, in accordance with one or more implementations. In the example shown in FIG. 11A, after the additional curable material 904 is applied to the portion of the substrate 106, a DLP projector 1110 may be used to cure desired locations (i.e., desired pixels) of the additional curable material 904. The DLP projector 1110 may include a light source 1112, or laser, and one or more moveable mirrors 1114 to direct the radiation source to specific portions of the additional curable material 904. In this way, mirrors 1114 are used to re-direct the laser/light source 1112 to specific designated areas all at once in a very targeted and precise/accurate manner. In one example, galvanometric mirrors may be used. Other mirror systems are contemplated as well.

FIG. 1lB illustrates schematically another implementation using a DLP projector 1110. In the example shown in FIG. 11B, the DLP projector 1110 is disposed inside the transparent roller 302 of a roller system 1115, such that as the substrate 106 travels over the roller surface, the DLP projector 1110 emits light/radiation through the mask 1020 to the desired locations (pixels/sub-pixels) of the additional curable material 904. In this case, the DLP projector 1110 would be disposed inside the roller 302 such that the DLP projector 1110 would not rotate as the roller 302 does. In other words, the DLP projector 1110 may be fixed centrally within the roller 302. In yet another example, the DLP projector 1110 inside the roller 302 may be used even without the use of the mask 1020. In this example, the light/radiation emitted from the DLP projector 1110 would be directed to the specific portions (pixels/sub-pixels) of the additional curable material 904 to cure. In this way, a DLP projector 1110 may be used with or without a mask 1020 to cure/obliterate.

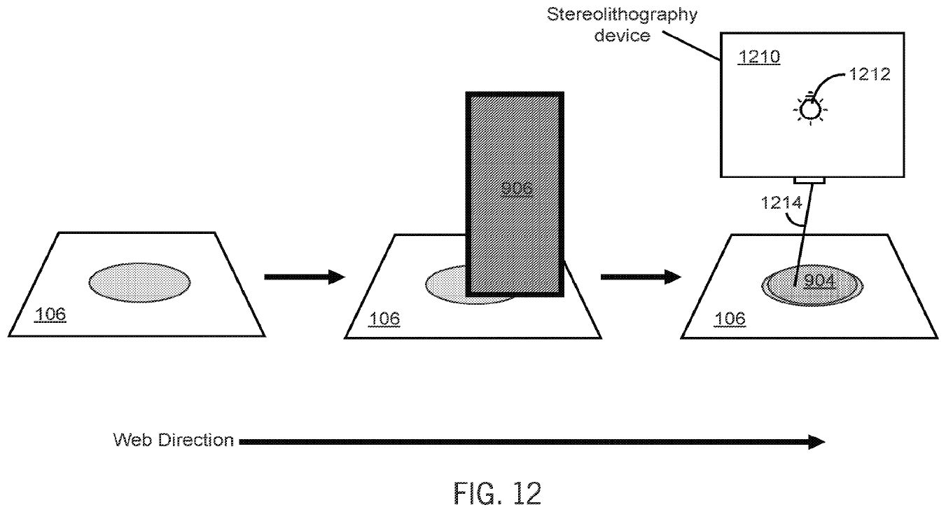

In yet another example, to cure at different wavelengths, at different exposure times, at different intensities, or a combination thereof, the image generation component 906 may be configured to cure using stereolithography. FIG. 12 illustrates schematically a stereolithography device 1210 used to generate an exemplary image formed in the cured material on the substrate 106 by one or more image generation components 906, in accordance with one or more implementations. In the example shown in FIG. 12, after the additional curable material 904 is applied to the portion of the substrate 106, a stereolithography device 1210 may be used to cure desired locations (i.e., desired pixels) of the additional curable material 904. The stereolithography device 1210 may include an internal radiation/light source 1212. In one example, the radiation/light source 1212 may be a laser 1214. In this case, the laser 1214 may be directed by the stereolithography device 1210 to certain optical structures (pixels/sub-pixels) in the additional curable material 904 to cure those specific regions and change those portions of the additional curable material 904 exposed to the laser 1214 to a different color. The color may be changed to black or a color dark enough to prevent the underlying optical structure(s) from reflecting or transmitting light (i.e., to render them inoperable). In another example, the stereolithography device 1210 may be disposed internally within a roller system, similar to that described above with respect to FIG. 11B for the DLP projector 1110. The stereolithography device 1210 may or may not be used in conjunction with a mask, such as the masks described above.

In one implementation, a combination of the various systems described above may be used. For example, the roller systems of FIGS. 3 and 10B (or 11B) 1015, 1115 may be combined to create a “one pass” system. In one example of this combined system, after the optical structures are formed in the curable material by passing under the roller 302 of either FIG. 3A or 3B (i.e., after the optical structures are embossed or imprinted in the curable lacquer), the roller system 1015, 1115 of FIG. 10B or 11B may be used to simultaneously cure and obliterate certain portions of the optical structures as the substrate 106 travels over the roller surface. In one example of this combined system, only a portion of the roller 302 contains surface elements 304 used to form optical structures in the curable lacquer, whereas another portion may contain a mask 1020, if used. For instance, half (or substantially half) of the roller 302 may contain surface elements 304 while the other half may contain the mask 1020. In another example, the entire surface of the roller 302 may contain surface elements 304 and the mask 1020 may be disposed along a portion or the entire surface of the roller 302 as well. In yet another example, the mask 1020 or screen may contain an outer layer having the surface elements 304 (static physical pixels) formed therein.

In some implementations, an optional step may be performed and the image generation component, or another component, such as those discussed above, may be configured to cure the non-cured portions of the other/additional curable material in a transparent state. In other words, after curing the additional material to obliterate certain optical structures by changing their color dark, additional curing may be performed to the non-obliterated optical structures to cure those portions of the additional curable material to a clear or transparent color. In this example, the curing may be performed at different wavelengths, intensities, and/or exposure times than those discussed above for curing to obliterate. That is, certain wavelengths may be used to cure a material to change to a dark color, whereas other different wavelengths may be used to cure a material to change to a clear or transparent color. In some implementations, an image generation component, or other component, that applies the additional curable material to the substrate (and/or on top of the previously cured material) may be configured to be able to apply different types of curable material at the same time (or sequentially), such that materials that change to a dark color upon curing are placed on/over certain optical structures (pixels/sub-pixels) to be obliterated and different curable materials that change to a clear or transparent color upon curing are placed on/over other certain optical structures (pixel/sub-pixels) to be stabilized (i.e., not obliterated).

The novel methods of obliterating by curing described above greatly improves the obliteration of optical structures (pixels/sub-pixels), since the obliteration may be done at the micro or nano scale, which improves accuracy and precision of obliterating and leads to a sharper optical image. Obliterating using ink may allow for precision in the 5-100 micron range (i.e., smallest ink spot size), but registration (e.g., mapping and aligning the ink to the desired location) is problematic since ink drops are liquid and the carrier/film is moving. Additionally, ink drops may deform and spread past the desired pixel and obliterate other pixels not intended to be obliterated. The enhanced laser systems described above using light to cure allows for greater control and to cure quickly at very small and precise spots, in some examples as small as 2-10 microns. This results in a higher resolution optical image. Registration using light to cure and obliterate is also improved in the disclosed systems, since there is greater control over where the light is directed. Further, using masks and light to cure specific portions of optical structures allows for instant obliteration of all desired pixels at once, since all of the desired pixels are exposed to the curing light at the same time.

Once the obliteration of specified optical structures is complete, the optical image is formed. The images may be continuous, or, as shown, may be variable. When the images are variable, the optical images may vary from print to print. This may make it possible for the printing equipment to print different digital optical images as the substrate passes through the printing equipment. In contrast to conventional techniques, exemplary implementations may digitally vary the ink printing and/or vary the optical images. By way of non-limiting example, one may print 10,000 labels in which an optical image is different on every label. This may enable greater security in industrial labeling and packaging, as well as in security documents such as driver's licenses, passports, paper currency, lottery tickets, government documents, and/or other security documents. Some implementations may be applicable to track and trace of products based on the optical variability of codes and/or other information encrypted onto the optical images.

In some implementations, translucent or transparent material may be used to overprint pixels that are not obliterated. The translucent or transparent material may be configured to act as a color filter. The color filter may be configured to increase an angle of observation of the optical image. The translucent or transparent material may include one or more of a lacquer, a UV ink, and/or other materials. The translucent or transparent material may have a high refractive index. In some implementations, the high refractive index may be greater than that of a material making up the optical structures of sub-pixels of the generic optical matrix. The index of refraction of a material making up the optical structures of sub-pixels of the generic optical matrix may be between approximately 1.4 and approximately 1.6. In some implementations, the high refractive index may be between approximately 1.75 and approximately 2. The high refractive index may be greater than 2. One reason for the difference in index of refraction between the generic optical matrix and the material used for overprinting is that when optical structures are covered by a material with the same index of refraction, the optical structure may become obliterated. In some implementations, overprinting pixels and/or sub-pixels may be performed with RGB or YMCK printing systems using inks in order to generate full color images where pixels and/or sub-pixels below the translucent or transparent inks continue to provide corresponding non-color effects.

The image being in an electronic format may facilitate a number of techniques for producing optical images. Examples of electronic formats may include one or more of JPEG, TIFF, GIF, BMP, PNG, DDS, TARGA, DWG, PRT, CMX, EPS, SVG, STL, ART, AI, PSD, PMD, QXD, DOC, 3DS, BLEND, DFF, FBX, MA, MAX, SKP, VRML, BAT, JSFL, CLS, JAVA, MPEG, RM, SWF, PAGES, PCX, PDD, SCT, DXF, DWF, SLDASM, WRL, and/or other electronic formats.

The image in an electronic format may be modifiable such that successively generated optical images are variable in that individual optical images are different from other optical images. For example, the optical image and the successive optical images may include a variable code that is different for different optical images. Examples of the variable codes may include one or more of a linear barcode, a matrix barcode (e.g., a QR code), an alphanumeric code, a graphical code, a 2D code, sequential barcodes, sequential numbers, an encrypted code, a datamatrix code, a matrix 2D code, an Aztec code, a moire code, invisible encrypted codes, a maxi code, and/or other variable codes. The optical image and the successive optical images may include a variable overt security feature and/or a variable covert security feature. An overt security feature may be configured to be used to identify an original document (or other object) by sight and/or touch. A covert security feature may become apparent when a document (or other object) is photocopied or scanned. That is, an additional action is required to activate a covert security feature.

Some implementations may be used in optical encoding. Codes may be variable in that they may include one or more of variable data, sequential numbers, variable codes, variable bar codes, variable images, optically variable matrix barcodes (e.g., QR codes), 2D codes, barcodes, sequential numbers, moire codes, variable databases, and/or other information. Some implementations may be used for tracking purposes. Codes may be encrypted or unencrypted. In some implementations, objects or products may be encoded with sequentially variable optical images. This may add an extra layer of security due to the fact that these optical images may also have sequentially hidden security characteristics. Even without the characteristic of optical hidden security, exemplary embodiments used with encoding offer a layer of security to the object or product that is impossible to duplicate on conventional printing equipment.

As mentioned above, the image component may include electronic storage configured to store the image or a negative of the image in an electronic format (e.g., in implementations in which image is in an electronic format). Electronic storage may comprise non-transitory storage media that electronically stores information. The electronic storage media of electronic storage may include one or both of system storage that is provided integrally (i.e., substantially non-removable) with a computing device and/or printing apparatus and/or removable storage that is removably connectable to a computing device and/or printing apparatus via, for example, a port (e.g., a USB port, a firewire port, etc.) or a drive (e.g., a disk drive, etc.). Electronic storage may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage may include one or more virtual storage resources (e.g., cloud storage, a virtual private network, and/or other virtual storage resources). Electronic storage may store software algorithms, information determined by processor(s), information received from a computing device and/or printing apparatus, and/or other information that enables image component to function as described herein.

The image component may include one or more processors configured to provide processing capabilities. The one or more processors may be configured to provide information associated with the image to one or more other components of system (e.g., in implementations in which image is in an electronic format). Examples of such information may include printing instructions to print the image, instructions to copy or store the image, instructions to change or modify the negative (e.g., change a value of a code on the image), and/or other information. The processor(s) may include one or more of a digital processor, an analog processor, a digital circuit designed to process information, an analog circuit designed to process information, a state machine, and/or other mechanisms for electronically processing information. In some implementations, the processor(s) may include a plurality of processing units, which may be physically located within the same device or a plurality of devices operating in coordination. The processor(s) may be configured to execute machine-readable instructions. The processor(s) may be configured to execute machine-readable instructions by software; hardware; firmware; some combination of software, hardware, and/or firmware; and/or other mechanisms for configuring processing capabilities on the processor(s).

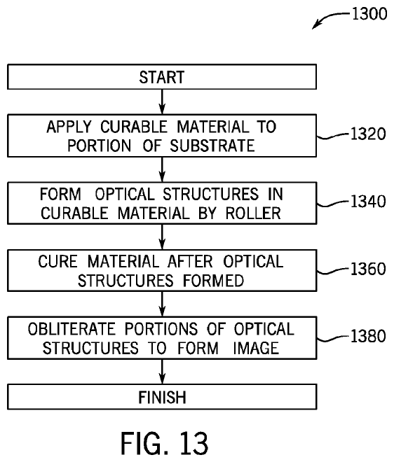

FIG. 13 illustrates a method 1300 for producing holographic optical images in a curable material, in accordance with one or more implementations. The operations of method 1300 presented below are intended to be illustrative. In some implementations, method 1300 may be accomplished with one or more additional operations not described, and/or without one or more of the operations discussed. Additionally, the order in which the operations of method 1300 are illustrated in FIG. 13 and described below is not intended to be limiting.

In some implementations, one or more operations of method 1300 may be implemented in one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1300 in response to instructions stored electronically on an electronic storage medium. The one or more processing devices may include one or more devices configured through hardware, firmware, and/or software to be specifically designed for execution of one or more of the operations of method.

At an operation 1320, a curable material may be applied to a designated portion of a substrate. The curable material may be applied by an applicator, such as a printer. The substrate may include a printed portion and a non-printed portion. Applying the curable material may include applying the curable material to the non-printed or printed portion of the substrate. As described above, the curable material may include a radiation curable material. The radiation curable material may include an embossable lacquer that is cured when exposed to ultraviolet light. Operation 1320 may be performed by an applicator or other component that is the same as or similar to the applicator described above in the first station (FIG. 2), in accordance with one or more implementations.

At an operation 1340, individual optical structures (physical static pixels and/or sub-pixels) are formed (e.g., embossed or imprinted) in (or on) the curable material by a transparent roller. The transparent roller may have microscopic or nanoscopic surface elements formed on an outside surface of the transparent roller. The surface elements on the transparent roller may form the optical structures in/on the curable material when the surface elements contact the curable material. The surface elements of the transparent roller may form a surface relief pattern. The optical structures on the curable material may form a generic optical matrix corresponding to the surface relief pattern. The surface relief pattern may be a negative of the generic optical matrix. The optical structures may include static physical pixels. Operation 1340 may be performed by a transparent roller or other component that is the same as or similar to the transparent roller described above in the second station (FIG. 3A or 3B), in accordance with one or more implementations.

At an operation 1360, a radiation source within the transparent roller may cure the curable material after the optical structures are formed on the curable material. The radiation source may be an ultraviolet light source. Operation 1360 may be performed by an ultraviolet light or other component that is the same as or similar to the ultraviolet lights described above in the second station (FIG. 3A or 3B), in accordance with one or more implementations.

At an operation 1380, an image generation component, or components, may obliterate portions of the optical structures to form a predetermined image. The predetermined image may include a holographic image. Non-obliterated portions of the optical structures may form the holographic image. The holographic image may include encrypted information. The obliterating may be based on digital information received by the image generation component, or components. The digital information may identify which portions of the optical structures are to be obliterated in the cured material. As discussed above, the obliterating may be performed a number of way. In one example, the obliterating may include laser ablating portions of the optical structures. In another example, the obliterating may include printing ink, or otherwise depositing pigment, over portions of the optical structures with an inkjet printer. In other examples, a three-dimensional printer may be used.

As described in detail above, the obliteration step at operation 1380 may include additional operations, such as applying another curable material to the portion of the substrate, such that the other curable material covers the optical structures, as well as curing portions of the other curable material corresponding to the portions of the optical structures to be obliterated, such that the cured portions of the other curable material prevent the corresponding portions of the optical structures to reflect light. The curing may include curing at different wavelengths, at different exposure times, at different intensities, or a combination thereof to cure the other curable material to different colors.

In one example, curing at different wavelengths, at different exposure times, at different intensities, or a combination thereof may include curing through a mask, wherein the mask comprises a screen configured to change at a predetermined frequency. The mask may prohibit radiation from contacting the additional curable material. The screen may include a liquid crystal display screen. The predetermined frequency may be every print cycle. These additional operations may be performed by a mask or other component that is the same as or similar to the masks described above with respect to FIGS. 10A and 10B, in accordance with one or more implementations.

In another example, curing at different wavelengths, at different exposure times, at different intensities, or a combination thereof may include curing using a digital light processor (DLP) projector. These additional operations may be performed by a DLP projector or other component that is the same as or similar to the DLP projector described above with respect to FIG. 11, in accordance with one or more implementations.

In yet another example, curing at different wavelengths, at different exposure times, at different intensities, or a combination thereof may include curing using stereolithography or a stereolithography device. These additional operations may be performed by a stereolithography device or other component that is the same as or similar to the stereolithography device described above with respect to FIG. 12, in accordance with one or more implementations.

In an optional step, not shown in FIG. 13, another operation may include curing the non-cured portions of the other curable material in a transparent state.

As described above, the pixels may be formed in the curable material on the substrate using a roller with a specific designed pixel/subpixel surface relief configuration on the roller surface, with the roller surface having surface reliefs therein.

One aspect (“aspect 1”) relates to a system for generating variable optical images in curable material using generic optical matrices, the system comprising an applicator configured to apply the curable material to a portion of a substrate supported by a carrier web; a transparent roller comprising surface elements formed on an outside surface of the transparent roller, the transparent roller being configured to form optical structures in the curable material, wherein the surface elements on the transparent roller form the optical structures in the curable material when the surface elements contact the curable material as the substrate travels over the outside surface of the transparent roller; a radiation source within the transparent roller configured to cure the curable material after the optical structures are formed in the curable material; and an image generation component configured to obliterate portions of the optical structures to form a predetermined image.

Another aspect (“aspect 2”) relates to aspect 1, wherein the system further comprises a flexographic printer configured to provide the carrier web supporting the substrate to the applicator.

Another aspect (“aspect 3”) relates to aspect 1, wherein the substrate comprises a printed portion and a non-printed portion, and wherein the applicator is configured to apply the curable material to the non-printed portion of the substrate.

Another aspect (“aspect 4) relates to aspect 1, wherein the curable material comprises a radiation curable material.

Another aspect (“aspect 5”) relates to aspect 4, wherein the radiation curable material comprises an embossable lacquer that is cured when exposed to ultraviolet light.

Another aspect (“aspect 6”) relates to aspect 1, wherein the applicator comprises a printer.

Another aspect (“aspect 7”) relates to aspect 1, wherein the surface elements of the transparent roller form a surface relief pattern and wherein the optical structures on the curable material form a generic optical matrix corresponding to the surface relief pattern.

Another aspect (“aspect 8”) relates to aspect 7, wherein the surface relief pattern is a negative of the generic optical matrix.

Another aspect (“aspect 9”) relates to aspect 1, wherein the optical structures comprise static physical pixels.

Another aspect (“aspect 10”) relates to aspect 1, wherein the radiation source is an ultraviolet light source.

Another aspect (“aspect 11”) relates to aspect 1, wherein the image generation component is configured to obliterate the portions of the optical structures based on digital information received by the image generation component, wherein the digital information identifies which portions of the optical structures to obliterate in the cured material.

Another aspect (“aspect 12”) relates to aspect 1, wherein the image generation component is configured to obliterate the portions of the optical structures by laser ablating portions of the optical structures.

Another aspect (“aspect 13”) relates to aspect 1, wherein the image generation component is configured to obliterate the portions of the optical structures by printing ink over portions of the optical structures with an inkjet printer.

Another aspect (“aspect 14”) relates to aspect 1, wherein the predetermined image comprises a holographic image, and wherein non-obliterated portions of the optical structures form the holographic image.

Another aspect (“aspect 15) relates to aspect 14, wherein the holographic image comprises encrypted information.

Another aspect (“aspect 16”) relates to aspect 1, wherein to obliterate the portions of the optical structures, the image generation component is configured to apply another curable material to the portion of the substrate, such that the other curable material covers the optical structures; and cure portions of the other curable material corresponding to the portions of the optical structures to be obliterated, such that the cured portions of the other curable material prevent the corresponding portions of the optical structures to reflect light.

Another aspect (“aspect 17”) relates to aspect 16, wherein the image generation component is configured to cure the portions of the other curable material at different wavelengths, at different exposure times, at different intensities, or a combination thereof to cure the other curable material to different colors.

Another aspect (“aspect 18”) relates to aspect 17, wherein to cure at different wavelengths, at different exposure times, at different intensities, or a combination thereof, the image generation component is configured to cure through a mask, wherein the mask comprises a screen configured to change at a predetermined frequency.

Another aspect (“aspect 19”) relates to aspect 18, wherein the screen comprises a liquid crystal display screen.

Another aspect (“aspect 20”) relates to aspect 18, wherein the predetermined frequency is every print cycle.

Another aspect (“aspect 21”) relates to aspect 17, wherein to cure at different wavelengths, at different exposure times, at different intensities, or a combination thereof, the image generation component is configured to cure using a digital light processor projector.

Another aspect (“aspect 22”) relates to aspect 17, wherein to cure at different wavelengths, at different exposure times, at different intensities, or a combination thereof, the image generation component is configured to cure using stereolithography.

Another aspect (“aspect 23”) relates to aspect 16, wherein the image generation component is further configured to cure non-cured portions of the other curable material in a transparent state.

Another aspect (“aspect 24”) relates to a method for producing holographic optical images in a curable material, the method comprising applying, by an applicator, a curable material to a portion of a substrate; forming optical structures in the curable material by a transparent roller, the transparent roller having surface elements formed on an outside surface of the transparent roller, wherein the surface elements on the transparent roller form the optical structures in the curable material when the surface elements contact the curable material; curing, by a radiation source within the transparent roller, the curable material after the optical structures are formed on the curable material; and obliterating, by an image generation component, portions of the optical structures to form a predetermined image.

Another aspect (“aspect 25”) relates to aspect 24, wherein the substrate comprises a printed portion and a non-printed portion, and wherein the applying comprises applying the curable material to the non-printed portion of the substrate.

Another aspect (“aspect 26”) relates to aspect 24, wherein the curable material comprises a radiation curable material.

Another aspect (“aspect 27”) relates to aspect 26, wherein the radiation curable material comprises an embossable lacquer that is cured when exposed to ultraviolet light.

Another aspect (“aspect 28”) relates to aspect 24, wherein the applicator comprises a printer.

Another aspect (“aspect 29”) relates to aspect 24, wherein the surface elements of the transparent roller form a surface relief pattern, and wherein the optical structures on the curable material form a generic optical matrix corresponding to the surface relief pattern.

Another aspect (“aspect 30”) relates to aspect 29, wherein the surface relief pattern is a negative of the generic optical matrix.

Another aspect (“aspect 31”) relates to aspect 24, wherein the optical structures comprise static physical pixels.

Another aspect (“aspect 32”) relates to aspect 24, wherein the radiation source is an ultraviolet light source.

Another aspect (“aspect 33”) relates to aspect 24, wherein the obliterating is based on digital information received by the image generation component, wherein the digital information identifies which portions of the optical structures to obliterate in the cured material.

Another aspect (“aspect 34”) relates to aspect 24, wherein the obliterating comprises laser ablating portions of the optical structures.

Another aspect (“aspect 35”) relates to aspect 24, wherein the obliterating comprises printing ink over portions of the optical structures with an inkjet printer.

Another aspect (“aspect 36”) relates to aspect 24, wherein the predetermined image comprises a holographic image, and wherein non-obliterated portions of the optical structures form the holographic image.

Another aspect (“aspect 37”) relates to aspect 36, wherein the holographic image comprises encrypted information.

Another aspect (“aspect 38”) relates to aspect 24, wherein the obliterating comprises applying another curable material to the portion of the substrate, such that the other curable material covers the optical structures; and curing portions of the other curable material corresponding to the portions of the optical structures to be obliterated, such that the cured portions of the other curable material prevent the corresponding portions of the optical structures to reflect light.

Another aspect (“aspect 39”) relates to aspect 38, wherein the curing comprises curing at different wavelengths, at different exposure times, at different intensities, or a combination thereof to cure the other curable material to different colors.

Another aspect (“aspect 40”) relates to aspect 39, wherein curing at different wavelengths, at different exposure times, at different intensities, or a combination thereof comprises curing through a mask, wherein the mask comprises a screen configured to change at a predetermined frequency.

Another aspect (“aspect 41”) relates to aspect 40, wherein the screen comprises a liquid crystal display screen.

Another aspect (“aspect 42”) relates to aspect 40, wherein the predetermined frequency is every print cycle.

Another aspect (“aspect 43”) relates to aspect 39, wherein curing at different wavelengths, at different exposure times, at different intensities, or a combination thereof comprises curing using a digital light processor projector.

Another aspect (“aspect 44”) relates to aspect 39, wherein curing at different wavelengths, at different exposure times, at different intensities, or a combination thereof comprises curing using stereolithography.

Another aspect (“aspect 45”) relates to aspect 38, further comprising curing non-cured portions of the other curable material in a transparent state.

Another aspect (“aspect 46”) relates to a transparent roller comprising a roller surface comprising an array of surface elements disposed on the roller surface, the array of surface elements including optical structures comprising an array of first pixels corresponding to a first color and second pixels corresponding to a second color, the first color being different from the second color; wherein individual ones of the pixels comprise sub-pixels, a given pixel comprising a first sub-pixel and a second sub-pixel, the first sub-pixel comprising a first optical structure corresponding to light to be reflected or transmitted from a substrate toward a left eye of a person from a first viewing angle, the second sub-pixel comprising a second optical structure corresponding to light to be reflected or transmitted from a substrate toward a right eye of the person from the first viewing angle, and the first sub-pixel and the second sub-pixel correspond to the color of light of the given pixels to be reflected or transmitted from a substrate.

Another aspect (“aspect 47”) relates to aspect 1, wherein a given optical structure includes one or more of a grating, a hologram, a kinegram, a Fresnel lens, a diffractive optically variable image device, a pixelgram, a holographic stereogram, a diffraction identification device, a dielectric structure, a volume hologram, an interference security image structure, a computer-generated hologram, an electron-beam grating, a metasurface hologram, a plasmonic hologram, a tensor hologram, a voxel type holograms a quantum hologram, a light field hologram, an artificial intelligent hologram and/or a structural color structures.

Another aspect (“aspect 48”) relates to a method for fabricating an optical image using a transparent roller that has an array of surface elements with surface reliefs that form a matrix of pixels and sub-pixels, the method comprising obtaining a substrate having a portion thereof comprising a curable material; forming in the curable material of the substrate, using a subset of the surface elements, surface reliefs that form an array of pixels in the curable material of the substrate wherein the array has first pixels corresponding to a first color and second pixels corresponding to a second color, the first color being different from the second color; and forming in the curable material of the substrate, using a subset of the surface elements, surface reliefs that form sub-pixels within individual ones of the pixels, a given pixel comprising a first sub-pixel and a second sub-pixel, the first sub-pixel comprising a first optical structure configured such that light reflected or transmitted by the first optical structure of the first sub-pixel is directed toward a left eye of a person observing the curable material of the substrate from the first viewing angle, the second sub-pixel comprising a second optical structure configured such that light reflected or transmitted by the second optical structure of the second sub-pixel is directed toward a right eye of the person observing the curable material of the substrate from the first viewing angle, the light reflected or transmitted by the first sub-pixel and the second sub-pixel being the corresponding color of the given pixel.

Another aspect (“aspect 49”) relates to the method of aspect 48, wherein the array further comprises third pixels corresponding to a third color; the third color is different from the first color and the second color; the given third pixel comprises a third sub-pixel and a fourth sub-pixel; the third sub-pixel comprises a third optical structure configured such that light reflected or transmitted by the third optical structure is directed toward a left eye of a person observing the curable material of the substrate from a second viewing angle; the fourth sub-pixel comprises a fourth optical structure configured such that light reflected or transmitted by the fourth optical structure is directed toward a right eye of a person observing the curable material of the substrate from the second viewing angle; and the light reflected or transmitted by the third sub-pixel and the fourth sub-pixel being the corresponding color of the given pixel.

Another aspect (“aspect 50”) relates to a system configured for fabricating variable digital optical images using a roller surface of a transparent roller, the variable digital optical images including different optical images instantly produced in a single printing cycle, the system comprising an image component configured to retain an image, the image being based on a geometry associated with a matrix of surface reliefs in the roller surface, the matrix having an arrayed motif of static physical pixels corresponding to color and sub-pixels corresponding to non-color effects, the pixels including first pixels corresponding to a first color and second pixels corresponding to a second color, the sub-pixels including first sub-pixels corresponding to a first non-color effect and second sub-pixels corresponding to a second non-color effect, the geometry indicating locations and colors of pixels to be formed in an embossable curable material on a substrate, the geometry further indicating locations and non-color effects of sub-pixels within the pixels, wherein a given non-color effect corresponds to one or more of viewing angle, viewing distance, polarization, intensity, scattering, refractive index, or birefringence; and an image generation component configured to use surface elements in the transparent roller's roller surface to form pixels and/or sub-pixels in the embossable curable material on the substrate according to the image, the pixels and/or sub-pixels forming an optical image corresponding to the image in the image component.

Another aspect (“aspect 51”) relates to aspect 50, wherein the optical image comprises one or more of a hologram, a stereo image, an optically variable device based image, a diffractive optically variable image, a zero order device based image, a blazed diffraction structure based image, a first order device based image, a dot matrix image, a pixelgram image, a structural color structure based image, a diffractive identification device based image, an interference security image structure based image, a kinegram image, an excelgram image, a diffractive optical element based image, a photonic structure based image, a nanohole based image, a computer generated hologram, an electron-beam generated optical structure, an interference pattern, a metasurface hologram, a plasmonic hologram, tensor hologram, a voxel type hologram, a quantum hologram, a light field hologram, an artificial intelligent hologram, or structural color structures.

Another aspect (“aspect 52”) relates to aspect 50, wherein the non-color effects of the sub-pixels give rise to one or more optical effects observable when viewing the optical image, the one or more optical effects including one or more of a three-dimensional optical effect, a two-dimensional optical effect, a dynamic optical effect, a scattering effect, a holographic white effect, a lens effect, a Fresnel lens effect, a brightness modulation effect, a lithographic effect, a stereogram effect, a nanotext and/or microtext effect, a hidden image effect, a moire effect, a concealed animated pattern effect, a covert laser readable (CLR) effect, a multiple background effect, a pearlescent effect, a true color image effect, a guilloche effect, an animation effect, an achromatic Fresnel effect, a dynamic CLR image, a kinematic images, a full parallax effect, a scratch holographic effect, a polarizing effect, a watermark effect, a metallic effect, a binary optical structure, a Fresnel prism, different viewing distances effect, any rainbow effect or structural colors effects.

Another aspect (“aspect 53”) relates to aspect 50, wherein individual ones of the sub-pixels reflect light at a specific viewing angle with a color corresponding to that of the individual pixels associated with the sub-pixels.

Another aspect (“aspect 54”) relates to aspect 50, wherein the optical image and successive optical images include a variable code that is different for different optical images, the variable codes including one or more of a linear barcode, a matrix barcode, an alphanumeric code, a graphical code, a 2D code, sequential barcodes, sequential numbers, an encrypted code, a datamatrix code, a matrix 2D code, an Aztec code, or a maxi code.

Another aspect (“aspect 55”) relates to the generic optical matrix of aspect 7, wherein the generic optical matrix comprises an array of pixels arranged as one of a square lattice, a hexagonal lattice, triangular lattice, rectangular lattice, a random arrangement, or a pseudorandom arrangement.

Another aspect (“aspect 56”) relates to aspect 55, wherein the array of pixels has a resolution in the range of one pixel per inch to 500,000 pixels per inch.

Another aspect (“aspect 57”) relates to the generic optical matrix of aspect 7, wherein individual ones of the pixels are shaped as a circle, a square, a rectangle, a line, an oval, a rounded square, or dots.

Another aspect (“aspect 58”) relates to anon-transitory computer-readable storage medium having instructions embodied thereon, the instructions being executable by one or more physical processors to perform the method of aspects 24 and 48.

Another aspect (“aspect 59”) relates to the system of aspect 50, wherein the optical image and the successive optical images include one or both of a variable overt security feature or a variable covert security feature.

Another aspect (“aspect 60”) relates to a system for generating variable optical images in curable material using generic optical matrices, the system comprising an applicator configured to apply the curable material to a portion of a substrate supported by a carrier web; a transparent roller; a transparent embossing plate coupled to an outer surface of the transparent roller, the transparent embossing plate comprising surface elements formed on an outside surface of the transparent embossing plate, the transparent embossing plate being configured to form optical structures in the curable material, wherein the surface elements on the transparent embossing plate form the optical structures in the curable material when the surface elements contact the curable material as the substrate travels over the outside surface of the transparent embossing plate; a radiation source disposed a distance away from the transparent roller configured to cure the curable material after the optical structures are formed in the curable material; and an image generation component configured to obliterate portions of the optical structures to form a predetermined image.

Another aspect (“aspect 61”) relates to the system of aspect 60, wherein the transparent roller comprises a transparent solid cylinder, a transparent hollow cylinder, or a transparent water filled cylinder.

Another aspect (“aspect 62”) relates to aspect 60, wherein the substrate comprises a printed portion and a non-printed portion, and wherein the applicator is configured to apply the curable material to the non-printed portion of the substrate.

Another aspect (“aspect 63”) relates to aspect 62, wherein the printed portion and the non-printed portion comprise variable shapes and sizes and are created with an inkjet head.

Another aspect (“aspect 64”) relates to aspect 60, wherein the optical structures comprise static physical optical pixels.

Another aspect (“aspect 65”) relates to aspect 64, wherein nanostructures inside of the optical pixels have a resolution of between 50 dots per inch and 200,000 dots per inch.

Another aspect (“aspect 66”) relates to aspect 60, wherein the generic optical matrices comprise pixels, the pixels comprising lithographic structures having depths between 0.2 microns to 100 microns.

Another aspect (“aspect 67”) relates to aspect 60, wherein the transparent roller and the transparent embossing plate, including the surface elements formed on an outside surface of the transparent embossing plate, comprise transparent materials such as polymers or plastics.

Another aspect (“aspect 68”) relates to aspect 60, wherein the system further comprises a nanoink coating configured to be applied to the predetermined image, such that the predetermined image becomes metallized or highly reflective.

Another aspect (“aspect 69”) relates to aspect 68, wherein the nanoink coating comprises a high diffractive index nanoink.

Although the present technology has been described in detail for the purpose of illustration based on what is currently considered to be the most practical and preferred implementations, it is to be understood that such detail is solely for that purpose and that the technology is not limited to the disclosed implementations, but, on the contrary, is intended to cover modifications and equivalent arrangements that are within the spirit and scope of the appended claims. For example, it is to be understood that the present technology contemplates that, to the extent possible, one or more features of any implementation can be combined with one or more features of any other implementation.

1. A system for generating variable optical images in curable material using generic optical matrices, the system comprising:
an applicator configured to apply the curable material to a portion of a substrate supported by a carrier web;
a transparent roller comprising surface elements formed on an outside surface of the transparent roller, the transparent roller being configured to form optical structures in the curable material, wherein the surface elements on the transparent roller form the optical structures in the curable material when the surface elements contact the curable material as the substrate travels over the outside surface of the transparent roller;
a radiation source within the transparent roller configured to cure the curable material after the optical structures are formed in the curable material; and
an image generation component configured to obliterate portions of the optical structures to form a predetermined image.

2. (canceled)

3. The system of claim 1, wherein the substrate comprises a printed portion and a non-printed portion, and wherein the applicator is configured to apply the curable material to the non-printed portion of the substrate.

4. The system of claim 1, wherein the curable material comprises a radiation curable material.

5. The system of claim 4, wherein the radiation curable material comprises an embossable lacquer that is cured when exposed to ultraviolet light.

6. (canceled)

7. The system of claim 1, wherein the surface elements of the transparent roller form a surface relief pattern and wherein the optical structures on the curable material form a generic optical matrix corresponding to the surface relief pattern.

8. The system of claim 7, wherein the surface relief pattern is a negative of the generic optical matrix.

9. The system of claim 1, wherein the optical structures comprise static physical pixels.

10. The system of claim 1, wherein the radiation source is an ultraviolet light source.

11. The system of claim 1, wherein the image generation component is configured to obliterate the portions of the optical structures based on digital information received by the image generation component, wherein the digital information identifies which portions of the optical structures to obliterate in the cured material.

12. The system of claim 1, wherein the image generation component is configured to obliterate the portions of the optical structures by laser ablating portions of the optical structures.

13. The system of claim 1, wherein the image generation component is configured to obliterate the portions of the optical structures by printing ink over portions of the optical structures with an inkjet printer.

14. The system of claim 1, wherein the predetermined image comprises a holographic image, and wherein non-obliterated portions of the optical structures form the holographic image.

15. The system of claim 14, wherein the holographic image comprises encrypted information.

16. The system of claim 1, wherein, to obliterate the portions of the optical structures, the image generation component is configured to:
apply another curable material to the portion of the substrate, such that the other curable material covers the optical structures; and
cure portions of the other curable material corresponding to the portions of the optical structures to be obliterated, such that the cured portions of the other curable material prevent the corresponding portions of the optical structures to reflect light.

17. The system of claim 16, wherein the image generation component is configured to cure the portions of the other curable material at different wavelengths, at different exposure times, at different intensities, or a combination thereof to cure the other curable material to different colors.

18. The system of claim 17, wherein to cure at different wavelengths, at different exposure times, at different intensities, or a combination thereof, the image generation component is configured to cure through a mask, wherein the mask comprises a screen configured to change at a predetermined frequency.

19. The system of claim 18, wherein the screen comprises a liquid crystal display screen.

20. The system of claim 18, wherein the predetermined frequency is every print cycle.

21. The system of claim 17, wherein to cure at different wavelengths, at different exposure times, at different intensities, or a combination thereof, the image generation component is configured to cure using a digital light processor projector.

22. The system of claim 17, wherein to cure at different wavelengths, at different exposure times, at different intensities, or a combination thereof, the image generation component is configured to cure using stereolithography.

23. The system of claim 16, wherein the image generation component is further configured to cure non-cured portions of the other curable material in a transparent state.

24. A method for producing holographic optical images in a curable material, the method comprising:
applying, by an applicator, a curable material to a portion of a substrate;
forming optical structures in the curable material by a transparent roller, the transparent roller having surface elements formed on an outside surface of the transparent roller, wherein the surface elements on the transparent roller form the optical structures in the curable material when the surface elements contact the curable material;
curing, by a radiation source within the transparent roller, the curable material after the optical structures are formed on the curable material; and
obliterating, by an image generation component, portions of the optical structures to form a predetermined image.

25-37. (canceled)

38. The method of claim 24, wherein the obliterating comprises:
applying another curable material to the portion of the substrate, such that the other curable material covers the optical structures; and
curing portions of the other curable material corresponding to the portions of the optical structures to be obliterated, such that the cured portions of the other curable material prevent the corresponding portions of the optical structures to reflect light.

39. The method of claim 38, wherein the curing comprises curing at different wavelengths, at different exposure times, at different intensities, or a combination thereof to cure the other curable material to different colors.

40. The method of claim 39, wherein curing at different wavelengths, at different exposure times, at different intensities, or a combination thereof comprises curing through a mask, wherein the mask comprises a screen configured to change at a predetermined frequency.

41. The method of claim 40, wherein the screen comprises a liquid crystal display screen.

42. The method of claim 40, wherein the predetermined frequency is every print cycle.

43. The method of claim 39, wherein curing at different wavelengths, at different exposure times, at different intensities, or a combination thereof comprises curing using a digital light processor projector.

44. The method of claim 39, wherein curing at different wavelengths, at different exposure times, at different intensities, or a combination thereof comprises curing using stereolithography.

45. The method of claim 38, further comprising curing non-cured portions of the other curable material in a transparent state.
